(19) United States
(12) Patent Application Publication
(10) Pub. No.: US 2024/0250106 A1
(43) Pub. Date: Jul. 25, 2024

(54) IMAGE SENSOR

(71) Applicant: SONY SEMICONDUCTOR SOLUTIONS CORPORATION, KANAGAWA (JP)

(72) Inventor: TAKUMI KAMIBAYASHI, KANAGAWA (JP)

(21) Appl. No.: 18/560,477

(22) PCT Filed: Feb. 22, 2022
(86) PCT No.: PCT/JP2022/007409

§ 371 Date: Nov. 13, 2023

(30) Foreign Application Priority Data
May 31, 2021 (JP) 2021-091939

(51) Int. Cl. H01L 27/146

(52) U.S. Cl. CPC H01L 27/14636; H01L 27/14634

(57) ABSTRACT

An image sensor of an embodiment of the present disclosure includes: a wiring layer including multiple wires extending in one direction; a first insulating layer with air gaps formed in at least some of regions between adjacent wires of the multiple wires; a first conducting film formed and embedded in a first surface of the first insulating layer in a first region including the air gaps and the adjacent wires between which the air gaps have been formed; and a second conducting film formed and embedded in the first surface of the first insulating layer in a second region not including the air gaps and the adjacent wires between which the air gaps have been formed. The second conducting film is thicker than the first conducting film.

### TECHNICAL FIELD

The present disclosure relates to, for example, an image sensor with an air gap between wires.

### BACKGROUND ART

In semiconductor devices, the space between wires connecting between and within elements has become narrower with the miniaturization of semiconductor integrated circuit elements. To cope with this, for example, PTL 1 discloses a semiconductor device in which an air gap is formed between wires to reduce the capacitance between the wires.

### CITATION LIST

### Patent Literature

PTL 1: Japanese Unexamined Patent Application Publication No. 2008-193104

### SUMMARY OF INVENTION

Incidentally, reduction of the wiring capacitance in a stacking direction is expected of an image sensor.

It is desirable to provide an image sensor that makes it possible to reduce the wiring capacitance in the stacking direction.

An image sensor according to an embodiment of the present disclosure includes: a wiring layer including multiple wires extending in one direction; a first insulating layer with air gaps formed in at least some of regions between adjacent wires of the multiple wires: a first conducting film formed and embedded in a first surface of the first insulating layer in a first region including the air gaps and the adjacent wires between which the air gaps have been formed; and a second conducting film formed and embedded in the first surface of the first insulating layer in a second region not including the air gaps and the adjacent wires between which the air gaps have been formed, the second conducting film being thicker than the first conducting film.

In the image sensor of the embodiment of the present disclosure, of the conducting films provided above the wiring layer including the multiple wires extending in one direction and formed and embedded in the first surface of the first insulating layer with the air gaps formed between the adjacent wires of the wiring layer, the first conducting film formed in the first region including the air gaps and the adjacent wires between which the air gaps have been formed is made thinner than the second conducting film formed in the second region not including the air gaps and the adjacent wires between which the air gaps have been formed. Thus, there is secured the distance between the multiple wires extending in the one direction and a conducting film (the first conducting film) formed above the wires.

### BRIEF DESCRIPTION OF DRAWINGS

FIG. 1 is a diagram illustrating an example of a vertical cross-sectional configuration of a wiring structure according to an embodiment of the present disclosure.

FIG. 2 is a diagram illustrating an example of a horizontal cross-sectional configuration of second and third layers illustrated in FIG. 1.

FIG. 3 is a diagram illustrating another example of a horizontal cross-sectional configuration of the wiring structure according to the embodiment of the present disclosure.

FIG. 4 is a diagram illustrating another example of a vertical cross-sectional configuration of the wiring structure according to the embodiment of the present disclosure.

FIG. 5A is a diagram illustrating an example of a process of manufacturing an image sensor illustrated in FIG. 1.

FIG. 5B is a diagram illustrating the example of the manufacturing process continued from FIG. 5A.

FIG. 5C is a diagram illustrating the example of the manufacturing process continued from FIG. 5B.

FIG. 5D is a diagram illustrating the example of the manufacturing process continued from FIG. 5C.

FIG. 5E is a diagram illustrating the example of the manufacturing process continued from FIG. 5D.

FIG. 5F is a diagram illustrating the example of the manufacturing process continued from FIG. 5E.

FIG. 5G is a diagram illustrating the example of the manufacturing process continued from FIG. 5F.

FIG. 5H is a diagram illustrating the example of the manufacturing process continued from FIG. 5E.

FIG. 51 is a diagram illustrating the example of the manufacturing process continued from FIG. 5F.

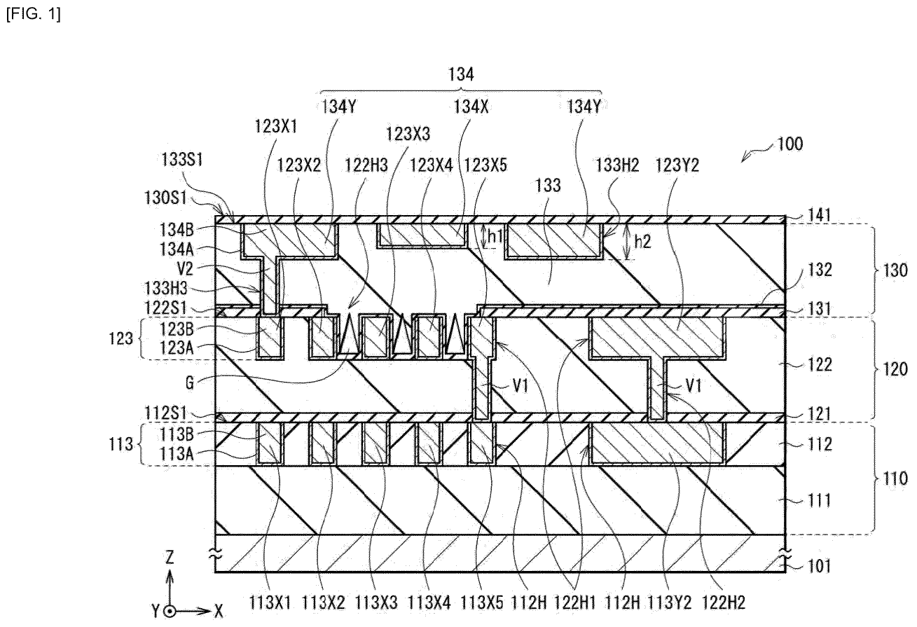

FIG. 6A is a diagram illustrating another example of the process of manufacturing the image sensor illustrated in FIG. 1.

FIG. 6B is a diagram illustrating the example of the manufacturing process continued from FIG. 6A.

FIG. 6C is a diagram illustrating the example of the manufacturing process continued from FIG. 6B.

FIG. 6D is a diagram illustrating the example of the manufacturing process continued from FIG. 6C.

FIG. 6E is a diagram illustrating the example of the manufacturing process continued from FIG. 6D.

FIG. 6F is a diagram illustrating the example of the manufacturing process continued from FIG. 6E.

FIG. 6G is a diagram illustrating the example of the manufacturing process continued from FIG. 6F.

FIG. 7 is a diagram illustrating another example of the vertical cross-sectional configuration of the wiring structure according to the embodiment of the present disclosure.

FIG. 8 is a diagram illustrating another example of the vertical cross-sectional configuration of the wiring structure according to the embodiment of the present disclosure.

FIG. 9 is a diagram illustrating an example of a vertical cross-sectional configuration of an image sensor according to an embodiment of the present disclosure.

FIG. 10 is a diagram illustrating an example of a schematic configuration of the image sensor illustrated in FIG. 9.

FIG. 11 is a diagram that the wiring structure illustrated in FIG. 1 has been applied to the image sensor illustrated in FIG. 9.

FIG. 12 is a diagram illustrating an example of sensor pixels and a readout circuit illustrated in FIG. 10.

FIG. 13 is a diagram illustrating an example of the sensor pixels and the readout circuit illustrated in FIG. 10.

FIG. 14 is a diagram illustrating an example of the sensor pixels and the readout circuit illustrated in FIG. 10.

FIG. 15 is a diagram illustrating an example of the sensor pixels and the readout circuit illustrated in FIG. 10.

FIG. 16 is a diagram illustrating an example of a coupling form of multiple readout circuits and multiple vertical signal wires.

FIG. 17 is a diagram illustrating an example of a horizontal cross-sectional configuration of the image sensor illustrated in FIG. 9.

FIG. 18 is a diagram illustrating an example of a horizontal cross-sectional configuration of the image sensor illustrated in FIG. 9.

FIG. 19 is a diagram illustrating an example of a wiring layout in a horizontal plane of the image sensor illustrated in FIG. 9.

FIG. 20 is a diagram illustrating an example of the wiring layout in the horizontal plane of the image sensor illustrated in FIG. 9.

FIG. 21 is a diagram illustrating an example of the wiring layout in the horizontal plane of the image sensor illustrated in FIG. 9.

FIG. 22 is a diagram illustrating an example of the wiring layout in the horizontal plane of the image sensor illustrated in FIG. 9.

FIG. 23A is a diagram illustrating an example of a process of manufacturing the image sensor illustrated in FIG. 9.

FIG. 23B is a diagram illustrating the example of the manufacturing process continued from FIG. 23A.

FIG. 23C is a diagram illustrating the example of the manufacturing process continued from FIG. 23B.

FIG. 23D is a diagram illustrating the example of the manufacturing process continued from FIG. 23C.

FIG. 23E is a diagram illustrating the example of the manufacturing process continued from FIG. 23D.

FIG. 23F is a diagram illustrating the example of the manufacturing process continued from FIG. 23E.

FIG. 23G is a diagram illustrating the example of the manufacturing process continued from FIG. 23F.

FIG. 24 is a diagram illustrating an example of a vertical cross-sectional configuration of an image sensor according to modification example 1 of the present disclosure.

FIG. 25 is a diagram illustrating an example of a vertical cross-sectional configuration of an image sensor according to modification example 2 of the present disclosure.

FIG. 26 is a diagram illustrating an example of a horizontal cross-sectional configuration of an image sensor according to modification example 3 of the present disclosure.

FIG. 27 is a diagram illustrating another example of the horizontal cross-sectional configuration of the image sensor according to modification example 3 of the present disclosure.

FIG. 28 is a diagram illustrating an example of a horizontal cross-sectional configuration of an image sensor according to modification example 4 of the present disclosure.

FIG. 29 is a diagram illustrating an example of a horizontal cross-sectional configuration of an image sensor according to modification example 5 of the present disclosure.

FIG. 30 is a diagram illustrating an example of a horizontal cross-sectional configuration of an image sensor according to modification example 6 of the present disclosure.

FIG. 31 is a diagram illustrating another example of the horizontal cross-sectional configuration of the image sensor according to modification example 6 of the present disclosure.

FIG. 32 is a diagram illustrating still another example of the horizontal cross-sectional configuration of the image sensor according to modification example 6 of the present disclosure.

FIG. 33 is a diagram illustrating an example of a circuit configuration of an image sensor according to modification example 7 of the present disclosure.

FIG. 34 is a diagram illustrating an example where the image sensor in FIG. 33 includes three substrates stacked on top of another according to modification example 8 of the present disclosure.

FIG. 35 is a diagram illustrating an example where logic circuits are separately formed in a substrate provided with the sensor pixels and a substrate provided with the readout circuits according to modification example 9 of the present disclosure.

FIG. 36 is a diagram illustrating an example where the logic circuit is formed in a third substrate according to modification example 10 of the present disclosure.

FIG. 37 is a diagram illustrating an example of a schematic configuration of an imaging system including the image sensor according to the above-described embodiment and its modification examples.

FIG. 38 is a diagram illustrating an example of an imaging procedure of the imaging system in FIG. 37.

FIG. 39 is a diagram illustrating an outline of configuration examples of a non-stacked solid-state image sensor and a stacked solid-state image sensor to which the technique according to the present disclosure may be applied.

FIG. 40 is a cross-sectional view illustrating a first configuration example of the stacked solid-state image sensor.

FIG. 41 is a cross-sectional view illustrating a second configuration example of the stacked solid-state image sensor.

FIG. 42 is a cross-sectional view illustrating a third configuration example of the stacked solid-state image sensor.

FIG. 43 is a cross-sectional view illustrating another configuration example of the stacked solid-state image sensor to which the technique according to the present disclosure may be applied.

FIG. 44 is a block diagram depicting an example of schematic configuration of a vehicle control system.

FIG. 45 is a diagram of assistance in explaining an example of installation positions of an outside-vehicle information detecting section and an imaging section.

FIG. 46 is a view depicting an example of a schematic configuration of an endoscopic surgery system.

FIG. 47 is a block diagram depicting an example of a functional configuration of a camera head and a camera control unit (CCU).

### MODES FOR CARRYING OUT THE INVENTION

With reference to the drawings, an embodiment of the present disclosure will be described in detail below. The following description is a specific example of the present disclosure, and the present disclosure is not limited to the following aspects. Furthermore, as for the disposition and dimensions of each component, the dimensional ratio, etc., the present disclosure is not limited to those illustrated in each drawing. It is noted that the order of description is as follows.
1. Embodiment (An example of an image sensor including conducting films having different film thicknesses in an air-gaps-forming region and the other regions on an upper layer of a wiring layer with air gaps between multiple wires extending in one direction)
1-1. Configuration of Wiring Structure
1-2. Method of Manufacturing Wiring Structure
1-3. Configuration of Image Sensor
1-4. Method of Manufacturing Image Sensor
1-5. Action and Effects
2. Modification Examples
2-1. Modification Example 1 (An example using a planar TG)
2-2. Modification Example 2 (An example using a Cu-Cu junction on a panel outer edge)
2-3. Modification Example 3 (An example where an offset is provided between sensor pixels and a readout circuit)
2-4. Modification Example 4 (An example where a silicon substrate provided in the readout circuit is insular)
2-5. Modification Example 5 (An example where a silicon substrate provided in the readout circuit is insular)
2-6. Modification Example 6 (An example where an FD is shared by four sensor pixels)
2-7. Modification Example 7 (An example where a column signal processing circuit includes a general column ADC circuit)
2-8. Modification Example 8 (An example where an image sensor includes three substrates stacked on top of another)
2-9. Modification Example 9 (An example where first and second substrates are each provided with a logic circuit)
2-10. Modification Example 10 (An example where a third substrate is provided with a logic circuit)
3. Application Example
4. Practical Application Examples

### 1. Embodiment

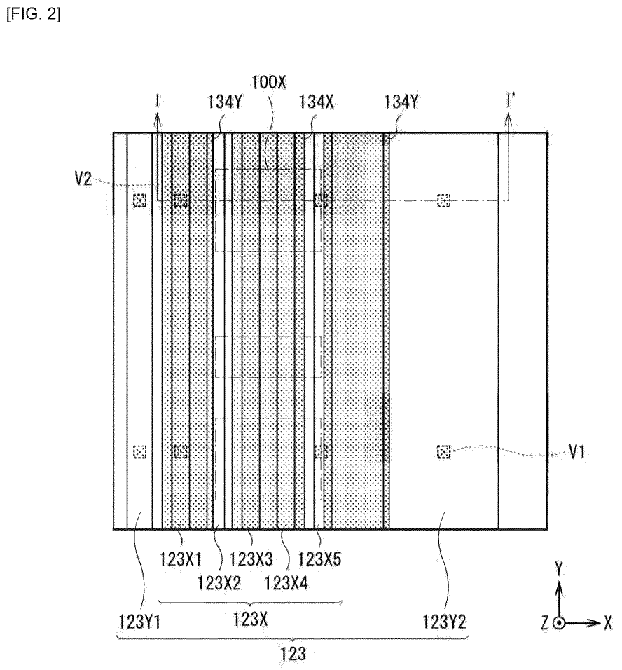

FIG. 1 schematically illustrates an example of a vertical cross-sectional configuration of a wiring structure (a wiring structure 100) according to an embodiment of the present disclosure. FIG. 2 schematically illustrates an example of a horizontal cross-sectional configuration of, within the wiring structure 100 illustrated in FIG. 1, a second layer 120 and a third layer 130. FIG. 1 corresponds to a cross section of the wiring structure 100 along a line I-I′ illustrated in FIG. 2. For example, the wiring structure 100 has a multi-layer wiring structure in which multiple wiring layers are stacked on top of another with an insulating layer sandwiched in between the wiring layers, and is applicable to, for example, an image sensor 1 to be described later.

The wiring structure 100 of the present embodiment is one that an insulating layer 133 for forming air gaps G, for example, between wires 123X1 to 123X5 is stacked on a wiring layer 123 including multiple wires (for example, the wires 123X1 to 123X5 and wires 123Y1 and 123Y2) extending in one direction (for example, a Y-axis direction). For example, multiple conducting films 134 having different thicknesses in a stacking direction (for example, a Z-axis direction) in an air-gaps-forming region 100X, where the air gaps G have been formed between adjacent wires in the wiring layer 123, and the other regions are formed and embedded in a surface of the insulating layer 133. Specifically, of the multiple conducting films 134, a conducting film 134X provided in the air-gaps-forming region 100X is formed to be thinner than conducting films 134Y formed in the other regions.

### 1-1. Configuration of Wiring Structure

The wiring structure 100 has a configuration in which a first layer 110, the second layer 120, and the third layer 130 are stacked in this order on a support substrate 101 including, for example, a silicon substrate. The first and second layers 110 and 120 include wiring layers 113 and 123 including multiple wires, respectively.

The first layer 110 includes insulating layers 111 and 112 stacked on top of each other in this order. The first layer 110 further includes the wiring layer 113 including multiple wires extending, for example, in the Y-axis direction: the wiring layer 113 is formed and embedded in a surface 112S1 of the insulating layer 112.

The insulating layer 111 is formed using, for example, silicon oxide (SiOₓ), silicon nitride (SiNₓ), or the like. The insulating layer 112 is formed using, for example, a low-dielectric constant material (a low-k material) having a relative dielectric constant (k) of 3.0 or lower. Specifically, examples of the material of the insulating layer 112 include carbon-containing silicon oxide (SiOC), SiOCH, porous silica, fluorine-doped silicon oxide (SiOF), inorganic SOG, organic SOG, an organic polymer such as polyarylether, etc.

The wiring layer 113 includes, as the multiple wires extending in the Y-axis direction, for example, wires 113X1 to 113X5 and wires 113Y1 and 113Y2. The wires 113X1 to 113X5 are formed in parallel, for example, at L/S=80/80 nm, where L denotes line, and S denotes space. For example, the wires 113X1 to 113X5 and the wires 113Y1 and 113Y2 are formed and embedded in an opening 112H provided on the surface 112S1 of the insulating layer 112. The wiring layer 113 includes, for example, a barrier metal 113A formed on a side surface and a bottom surface of the opening 112H and a metal film 113B embedded with the opening 112H. Examples of a material of the barrier metal 113A include a simple substance of Ti (titanium) or Ta (tantalum), an alloy of those, etc. Examples of a material of the metal film 113B include metallic materials containing low-resistance metal, such as Cu (copper), W (tungsten), or aluminum (Al), as a main constituent.

The second layer 120 includes insulating layers 121 and 122 stacked on top of each other in this order. The second layer 120 further includes the wiring layer 123 including multiple wires extending, for example, in the Y-axis direction, as with the wiring layer 113: the wiring layer 123 is formed and embedded in a surface 122S1 of the insulating layer 122.

For example, in a case where the wiring layer 113 is formed using copper (Cu), the insulating layer 121 is for preventing the diffusion of copper (Cu). The insulating layer 121 is formed using, for example, SiCN. The insulating layer 122 is formed using, for example, a low-dielectric constant material (a low-k material) having a relative dielectric constant (k) of 3.0 or lower. Specifically, examples of the material of the insulating layer 122 include carbon-containing silicon oxide (SiOC), SiOCH, porous silica, fluorine-doped silicon oxide (SiOF), inorganic SOG, organic SOG, an organic polymer such as polyarylether, etc.

The wiring layer 123 corresponds to a specific example of a “wiring layer” of the present disclosure. The wiring layer 123 includes, as the multiple wires extending in the Y-axis direction, for example, the wires 123X1 to 123X5 and the wires 123Y1 and 123Y2. As with the wires 113X1 to 113X5, the wires 123X1 to 123X5 are formed in parallel, for example, at L/S=80/80 nm, where L denotes line, and S denotes space. For example, the wires 123X1 to 123X5 and the wires 123Y1 and 123Y2 are formed and embedded in an opening 122H provided on the surface 122S1 of the insulating layer 122. The wiring layer 123 includes, for example, a barrier metal 123A formed on a side surface and a bottom surface of the opening 122H and a metal film 123B embedded with the opening 122H. Examples of a material of the barrier metal 123A include a simple substance of Ti (titanium) or Ta (tantalum), an alloy of those, etc. Examples of a material of the metal film 123B include metallic materials containing low-resistance metal, such as Cu (copper), W (tungsten), or aluminum (Al), as a main constituent. The wires 123X1 to 123X5 and 113Y1 and 113Y2 and the wires 113X1 to 113X5 and 113Y1 and 113Y2 of the wiring layer 113 are stacked on top of each other in the Z-axis direction, respectively, and are electrically coupled to each other, for example, through a via V1 at a predetermined position.

The second layer 120 is further provided with openings 122H3 between adjacent wires. Specifically, for example, the openings 122H3 are provided on portions of the insulating layer 122 between the wires 123X2 and 123X3, between the wires 123X3 and 123X4, and between the wires 123V4 and 123X5.

The third layer 130 includes insulating layers 131, 132, and 133 stacked on top of another in this order. The third layer 130 further includes the multiple conducting films 134 formed and embedded in a surface 133S1 of the insulating layer 133.

In the present embodiment, the above-described openings 122H3 provided between the wires 123X2 and 123X3, between the wires 123X3 and 123X4, and between the wires 123V4 and 123X5 are blocked with the insulating layer 133. Thus, air gaps G that decrease the capacitance between wires running parallel to one another are formed between the wires 123X2 and 123X3, between the wires 123X3 and 123X4, and between the wires 123V4 and 123X5. For example, as illustrated in FIG. 2, the air gaps G are formed in respective partial regions between the wires 123X2 and 123X3, between the wires 123X3 and 123X4, and between the wires 123V4 and 123X5. Such a region where air gaps have been formed between adjacent wires is referred to as the air-gaps-forming region 100X. Regions of air gaps are not limited to these: alternatively, air gaps G may be formed over the respective entire regions between the wires 123X2 and 123X3, between the wires 123X3 and 123X4, and between the wires 123V4 and 123X5. Furthermore, air gaps G may also be formed between other wires extending in the Y-axis direction besides the wires 123X1 to 123X6.

For example, in a case where the wiring layer 123 is formed using copper (Cu), the insulating layer 131 is for preventing the diffusion of copper (Cu), and corresponds to a specific example of a “barrier film” of the present disclosure. The insulating layer 131 is formed on the second layer 120 except for a part. Specifically, it is provided to cover the insulating layer 122, the embedded wire 123X1, portions of the wires 123X3 and 123X5 provided with the openings 122H3 on their one side between adjacent wires, and the wires 123Y1 and 123Y2, except for the above-described openings 122H3. In other words, the insulating layer 131 is formed on the outside of the openings 122H3, and has its side surfaces above the wires 123X3 and 123X5. The insulating layer 131 is formed using, for example, SiCN.

For example, in a case where the wiring layer 123 is formed using copper (Cu), the insulating layer 132 is for preventing the diffusion of copper (Cu) and the ingress of moisture, and corresponds to a specific example of a “second insulating layer” of the present disclosure. The insulating layer 132 is able to be formed using an insulating material that prevents the diffusion of copper (Cu) and a manufacturing process that provides an excellent step coverage. Specifically, the insulating layer 132 is able to be formed using, for example, silicon nitride (SiNₓ), SiC, SiCₓN_{y}, or the like and, for example, an atomic layer deposition (ALD) method.

The insulating layer 133 corresponds to a specific example of a “first insulating layer” of the present disclosure. The insulating layer 133 is provided on the insulating layer 132 and is for forming the air gaps G between the wiring layers within the openings 122H3. Specifically, the insulating layer 133 is for forming the air gaps G between the wiring layers 123X2 and 123X3, between the wiring layers 123X3 and 123X4, and between the wiring layers 123X4 and 123X5. The insulating layer 133 is formed using a low-coverage, low-k material having, for example, a relative dielectric constant (k) of 3.0 or lower. Specifically, examples of the material of the insulating layer 133 include carbon-containing silicon oxide (SiOC), SiOCH, porous silica, fluorine-doped silicon oxide (SiOF), inorganic SOG, organic SOG, an organic polymer such as polyarylether, etc.

The conducting film 134 is a wiring layer provided just above the wiring layer 123 with the air gaps G between adjacent wires: the multiple conducting films 134 are formed and embedded in the insulating layer 133. The conducting films 134 are exposed on the surface 133S1 of the insulating layer 133, and form the same plane as the insulating layer 133. In the present embodiment, as described above, the conducting films 134 include the conducting films 134X and 134Y having different thicknesses in the Z-axis direction in the air-gaps-forming region 100X and the other regions. Specifically, the thickness (h1) of the conducting film 134X provided in the air-gaps-forming region 100X is thinner than the thickness (h2) of the conducting films 134Y (h1<h2). This conducting film 134X corresponds to a specific example of a “first conducting film” of the present disclosure, and the conducting films 134Y correspond to a specific example of a “second conducting film” of the present disclosure. Furthermore, the air-gaps-forming region 100X corresponds to a “first region” of the present disclosure, and the other regions correspond to a “second region” of the present disclosure. The conducting film 134X is provided, for example, above the wires 123X3 and 123X4 with the air gaps G formed on its both sides between adjacent wires. The conducting films 134Y are provided, for example, above the wires 123X1, 123Y1, and 123Y2 with no air gaps G formed between adjacent wires and above the wires 123X2 and 123X5 with the air gaps G formed only on their one side between adjacent wires.

The conducting films 134X and 134Y are formed and embedded in openings 133H1 and 133H2 provided on the surface 133S1 of the insulating layer 133, respectively. Furthermore, in a planar view, the opening 133H1 embedded with the conducting film 134Y provided to extend from the wire 123X1 to the wire 123X2 is further provided with an opening 133H3 that goes through the insulating layers 131, 132, and 133 and reaches the wire 123X1. The conducting film 134Y is embedded in this opening 133H3 as well, and is electrically coupled to the wire 123X1.

The conducting films 134X and 134Y each include a barrier metal 133A formed on a side surface and a bottom surface of each of the openings 133H1, 133H2, and 133H3 and a metal film 123B embedded with each of the openings 133H1, 133H2, and 133H3. Examples of a material of the barrier metal 134A include a simple substance of Ti (titanium) or Ta (tantalum), an alloy of those, etc. Examples of a material of the metal film 134B include metallic materials containing low-resistance metal, such as Cu (copper), W (tungsten), or aluminum (Al), as a main constituent.

A surface 130S1 of the third layer 130 may be covered with, for example, an insulating layer 141 formed using SiCN.

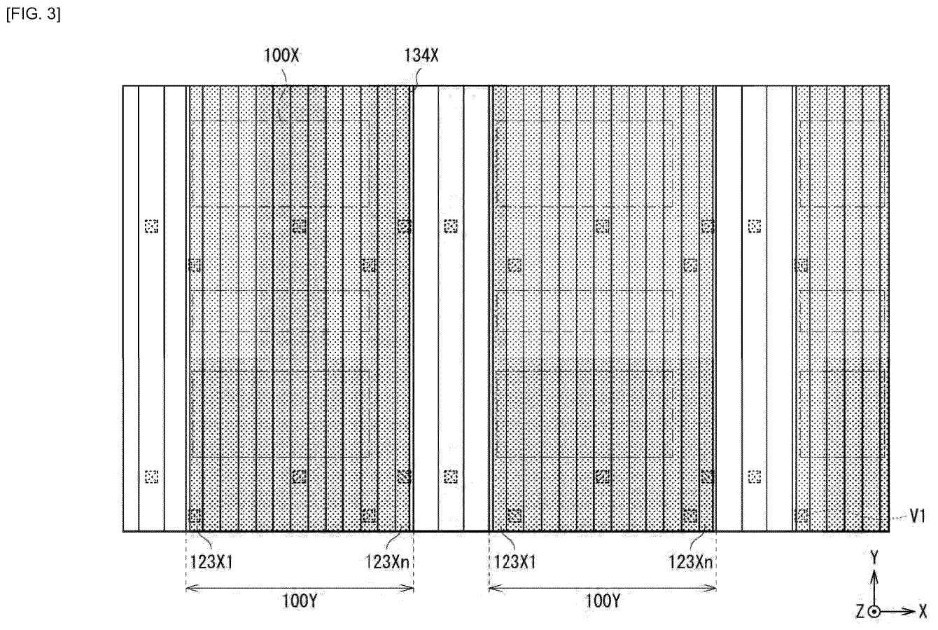

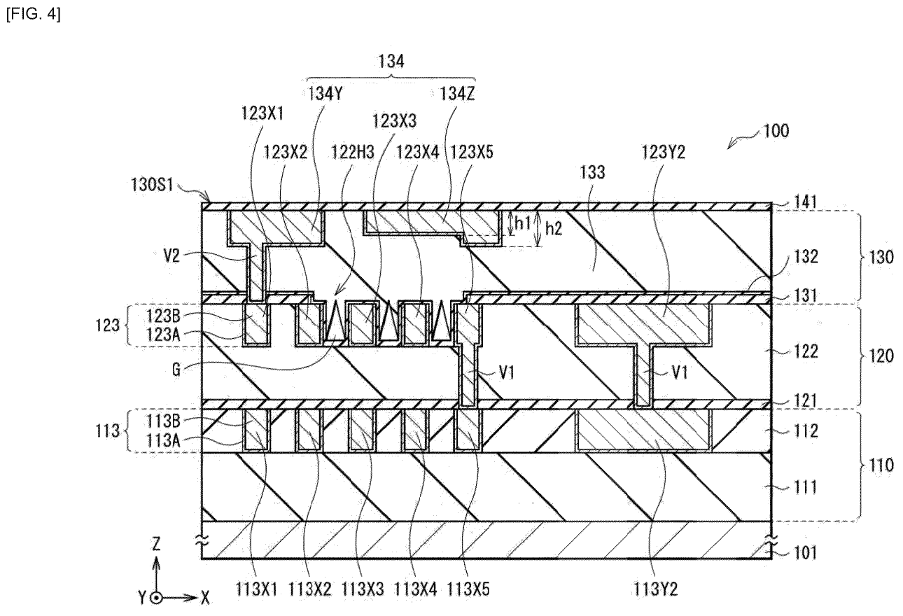

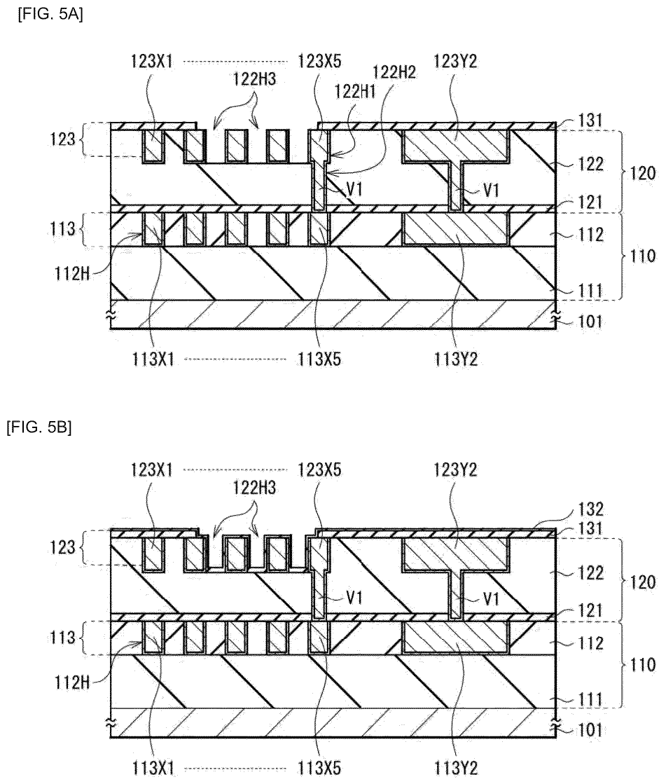

It is noted that the layout of the wiring layers 113 and 123 including the multiple wires extending in the Y-axis direction and the conducting films 134 is not limited to those illustrated in FIGS. 1 and 2. For example, the layout illustrated in FIG. 3 may be adopted. Furthermore, FIGS. 1 and 2 illustrate an example in which the conducting films 134X and 134Y having different thicknesses are formed independently of one another; however, they are not limited to this. For example, as illustrated in FIG. 4, there may be provided a conducting film 134Z formed to extend from above the wire 123X3 that air gaps G have been formed on its both sides between adjacent wires to above the wire 123X5 that an air gap G has been formed only on its one side between adjacent wire. In that case, the conducting film 134Z has different in-plane thicknesses (h1 and h2).

### 1-2. Method of Manufacturing Semiconductor Device

First, the first layer 110 is formed in such a way that the insulating layer 111 and the insulating layer 112 are sequentially formed on the support substrate 101, and after that the wiring layer 113 including the wires 113X1 to 113X5 and the wires 113Y1 and 113Y2 is formed and embedded in the insulating layer 112. Then, the insulating layer 121 and the insulating layer 122 are sequentially formed on the first layer 110. Next, openings 122H1 and 122H2 are formed by patterning the insulating layer 122, for example, by photolithography and etching. Then, the barrier metal 123A is formed on respective side surfaces and bottom surfaces of the openings 122H1 and 122H2, for example, by means of a sputter, and after that, the metal film 123B is formed inside the openings 122H1 and 122H2, for example, by means of plating. After that, the surfaces of the insulating layers 122 and 123 are ground. Thus, there is formed the second layer 120 with the wires 123X1 to 123X5 and 123Y2, etc. embedded in the surface of the insulating layer 122.

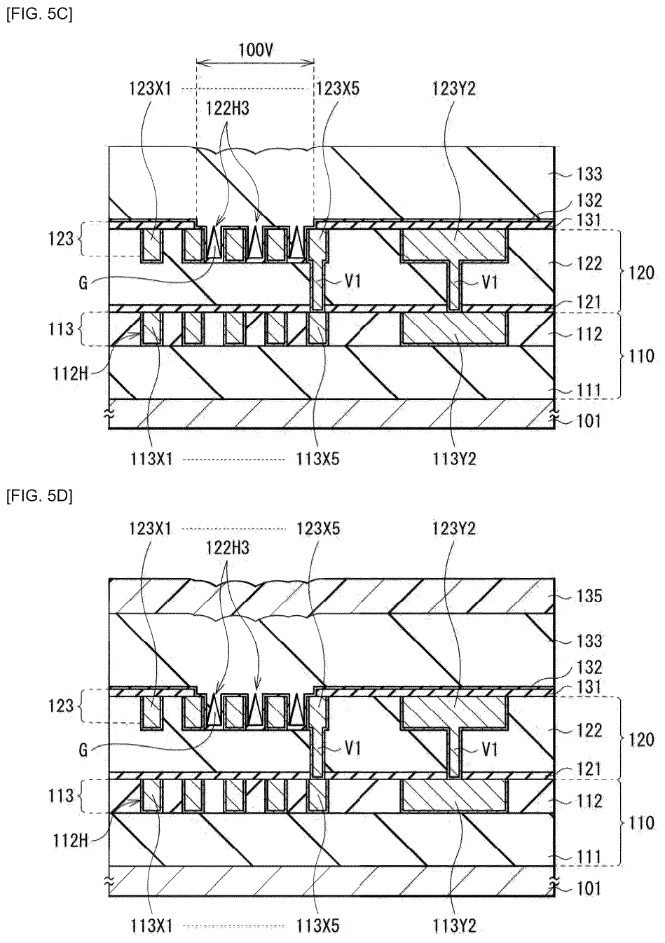

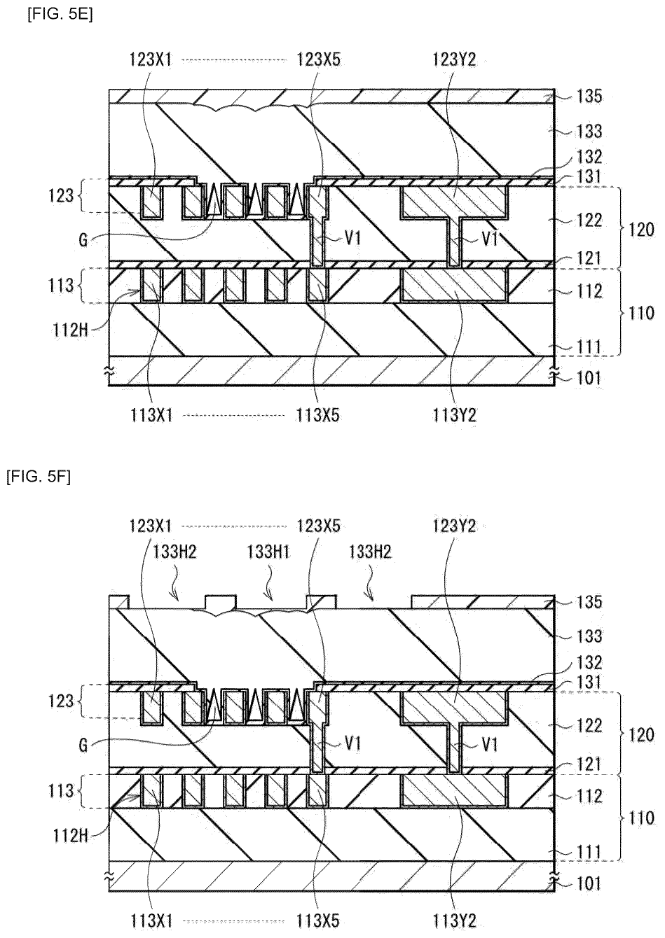

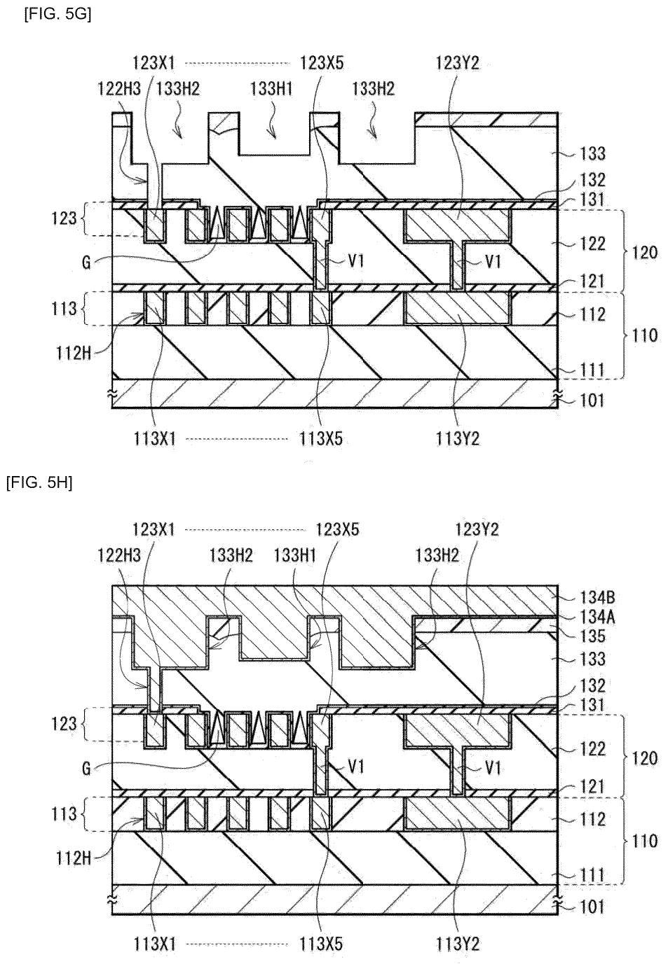

Next, as illustrated in FIG. 5A, as the insulating layer 131, an SiCN film is formed on the second layer 120, for example, by using a CVD method. Then, as illustrated in FIG. 5A, the SiCN film and the insulating layer 122 are patterned, for example, by photolithography and etching to form the openings 122H3 between the wires 123X2 and 123X3, between the wires 123X3 and 123X4, and between the wires 123X4 and 123X5.

Then, as illustrated in FIG. 5B, an SiCN film is formed on the insulating layer 131 and side surfaces and bottom surfaces of the openings 122H3, for example, by using an ALD method to form the insulating layer 132 having a film thickness of, for example, 30 nm to 50 nm. After that, as illustrated in FIG. 5C, the insulating layer 133 including, for example, SiOCH and having a film thickness of, for example, 400 nm to 500 nm is formed, for example, by using the CVD method. Thus, the openings 122H3 are blocked, and air gaps G are formed between the wires 123X2 and 123X3, between the wires 123X3 and 123X4, and between the wires 123X4 and 123X5. Furthermore, at this time, the surface of the insulating layer 133 formed in the air-gaps-forming region 100X is formed with a step height (a depression) by the insulating layer 133 getting into the openings 122H3.

Next, for the purpose of reducing the step height on the surface of the insulating layer 133, as illustrated in FIG. 5D, an SiO film 135 having a film thickness of, for example, 100 nm to 1000 nm is formed on the insulating layer 133, for example, by using the CVD method. Then, as illustrated in FIG. 5E, the SiO film 135 is polished, for example, by using a CMP (chemical mechanical polishing) method to planarize a surface of the SiO film 135. Thus, the thickness of the SiO film 135 in the air-gaps-forming region 100X becomes self-alignedly thicker than that is in the other regions.

Next, as illustrated in FIGS. 5F and 5G, the openings 133H1 and 133H2 are formed in the air-gaps-forming region 100X and the other regions, respectively, for example, by dry etching. At this time, an etching condition that the etching rate of the insulating layer 133 is higher than the SiO film 135 is selected. This makes the depth of the opening 133H1 provided in the air-gaps-forming region 100X self-alignedly shallower than the openings 133H2 in the other regions. After that, as illustrated in FIG. 5G, the opening 133H3 that reaches the wire 123X1 is formed within the opening 133H2 provided above the wire 123X1, for example, by photolithography and etching.

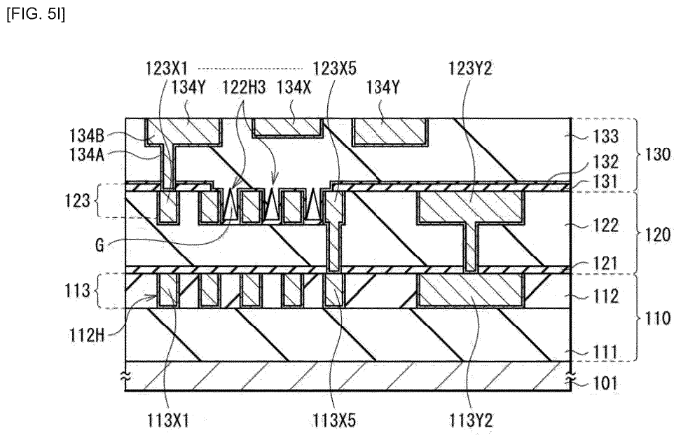

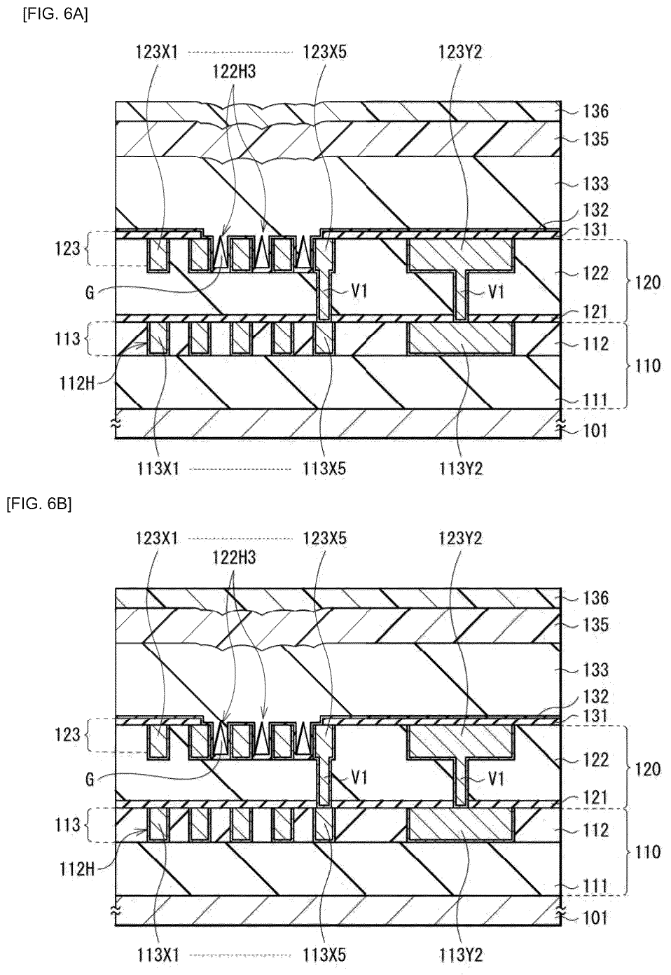

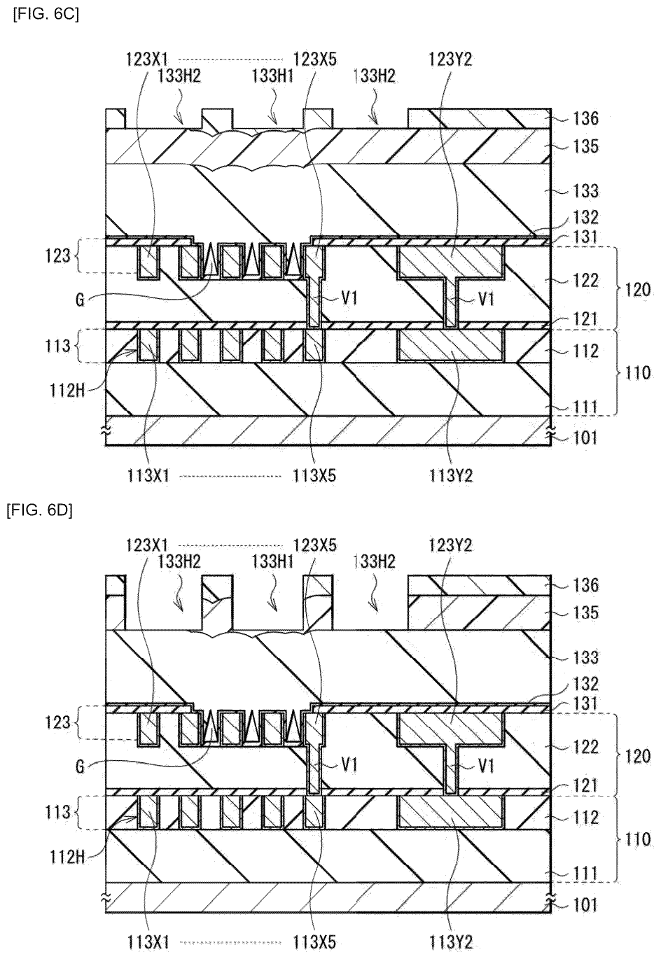

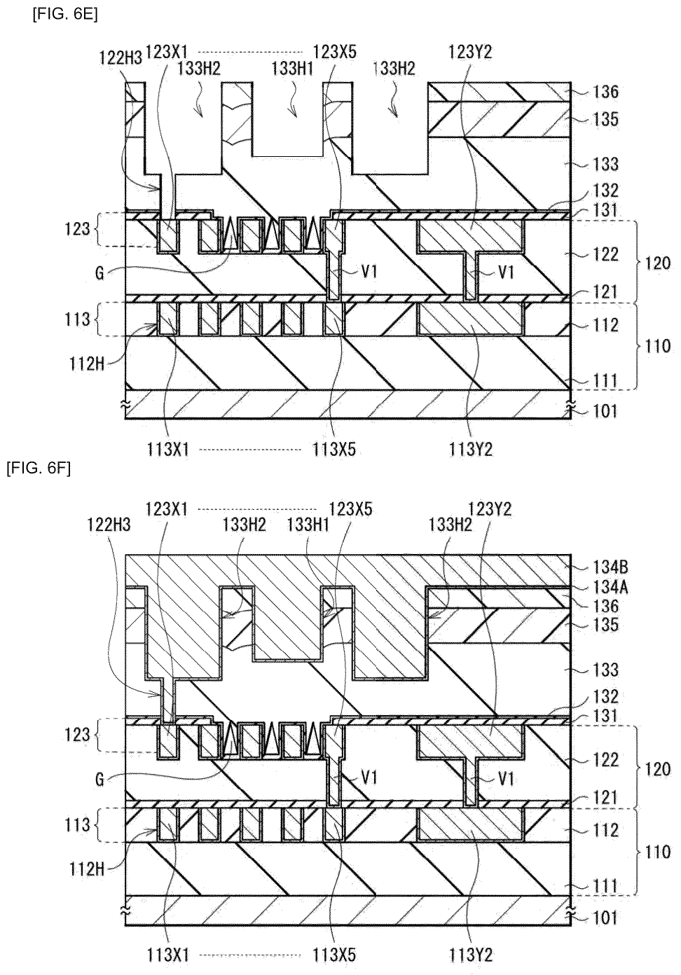

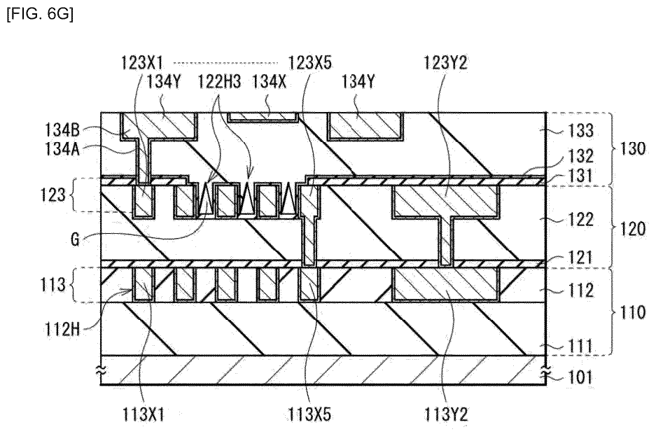

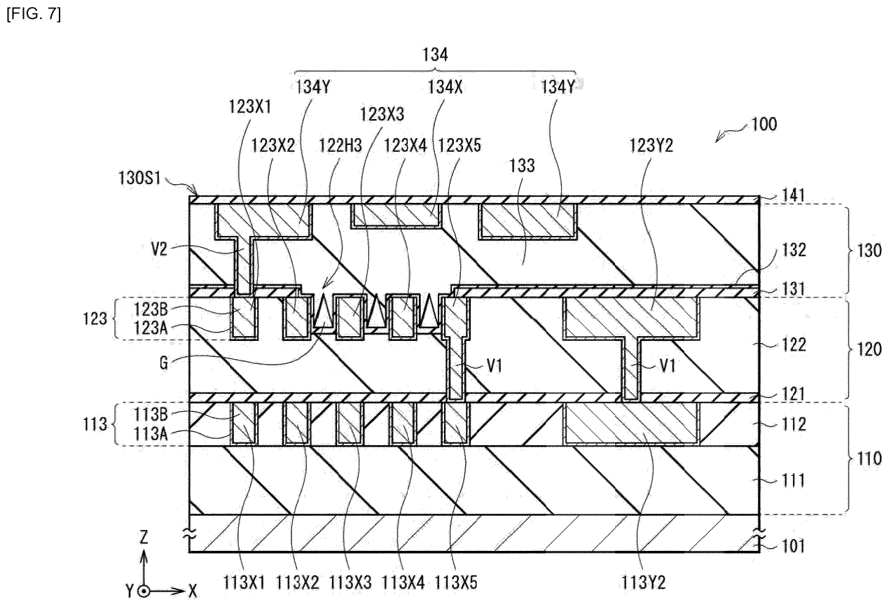

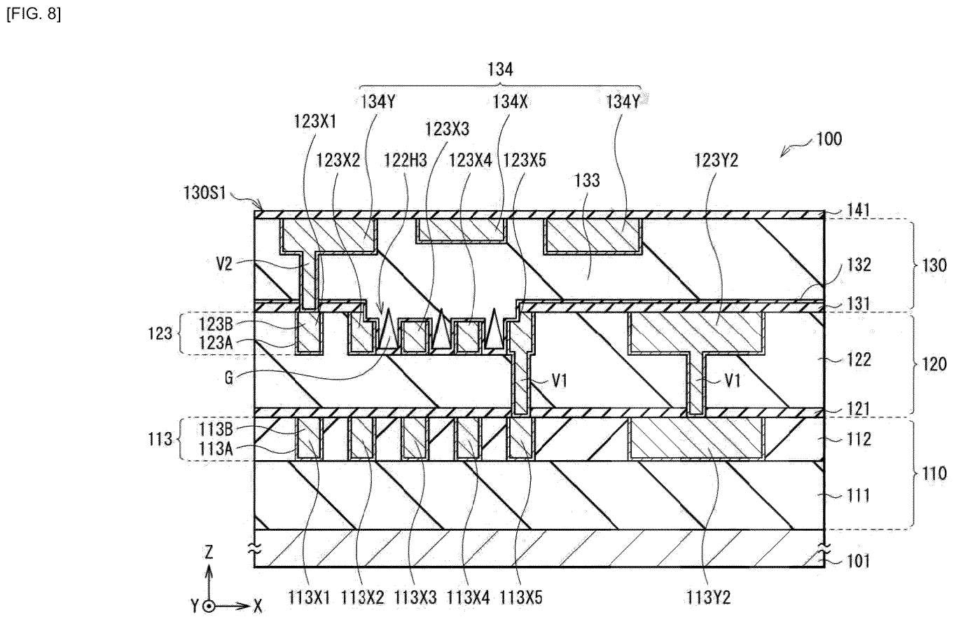

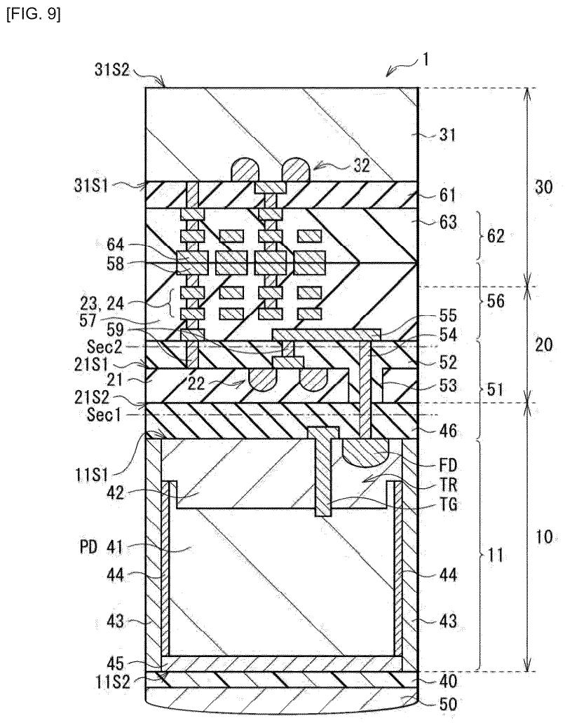

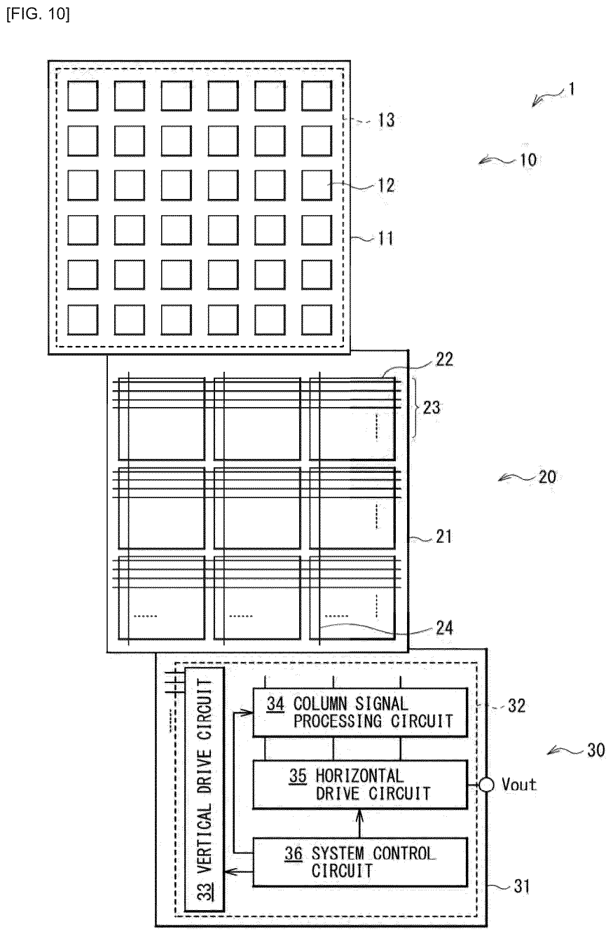

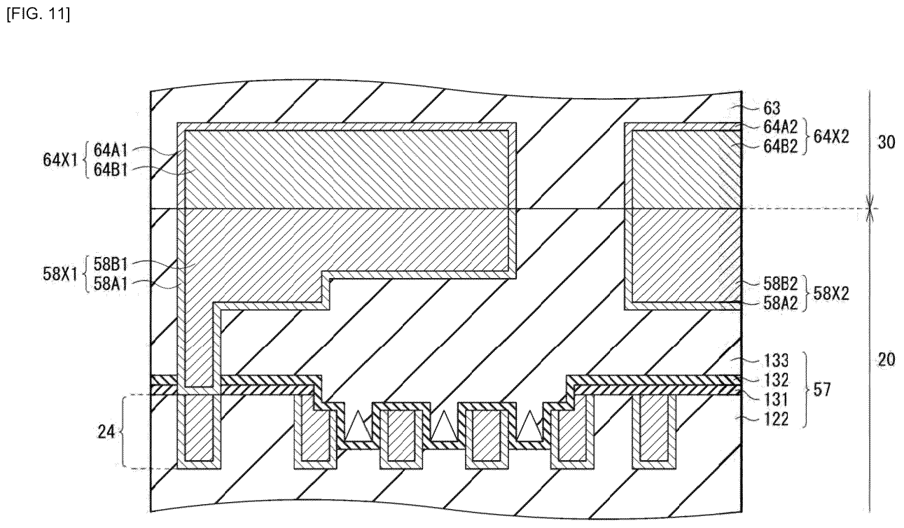

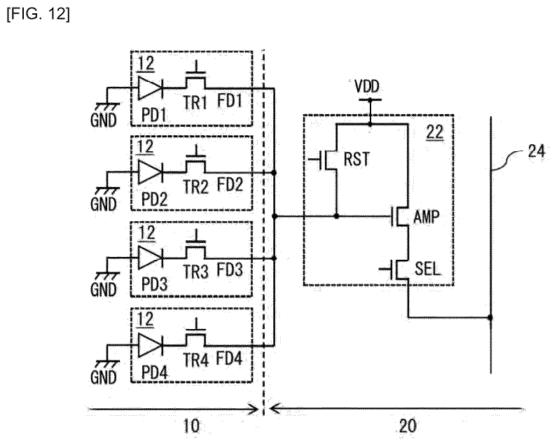

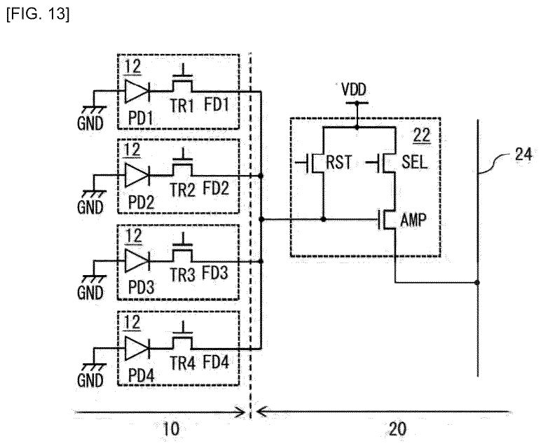

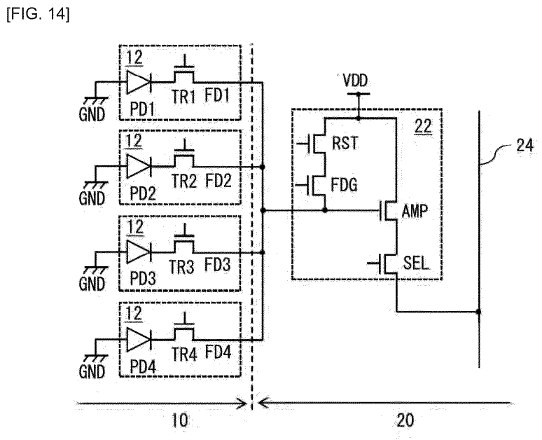

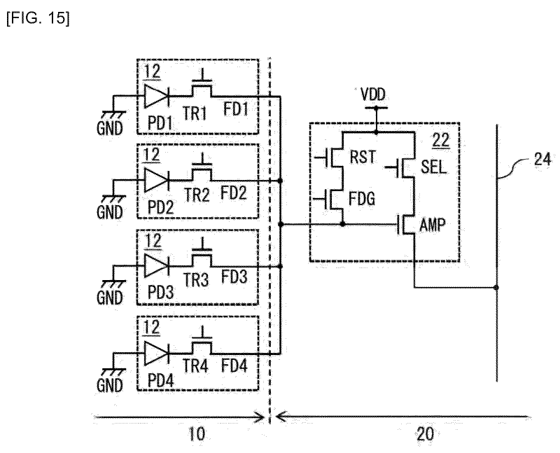

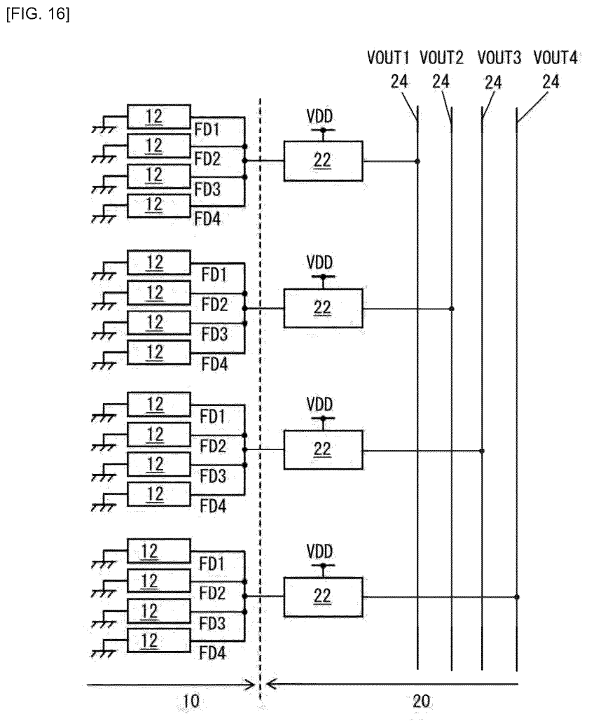

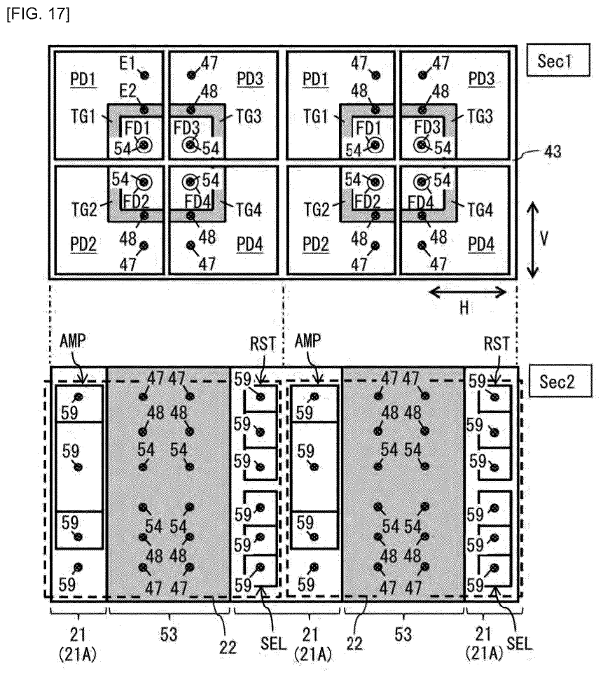

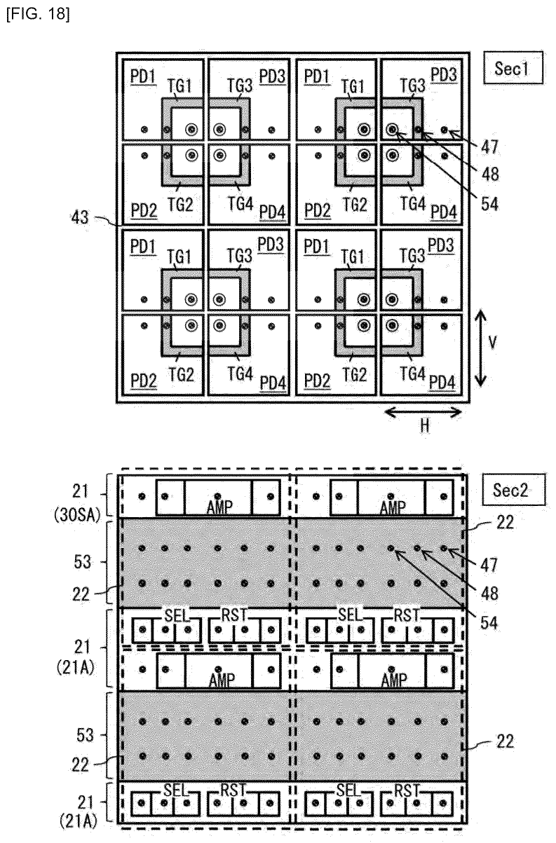

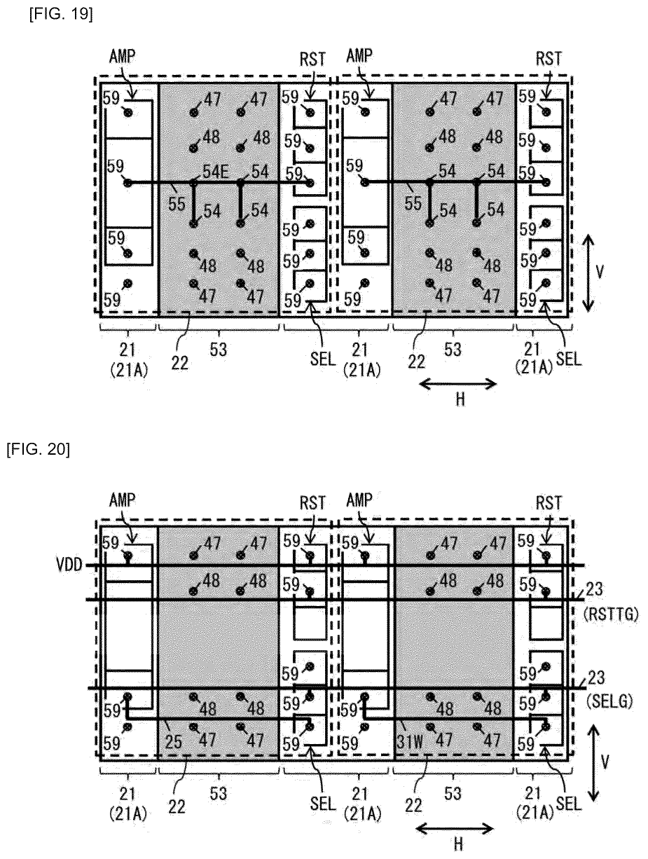

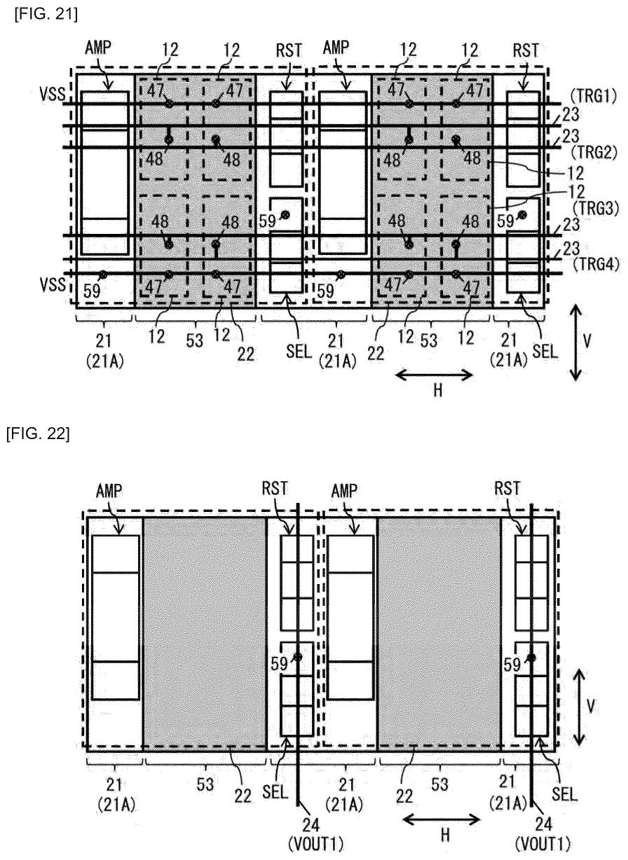

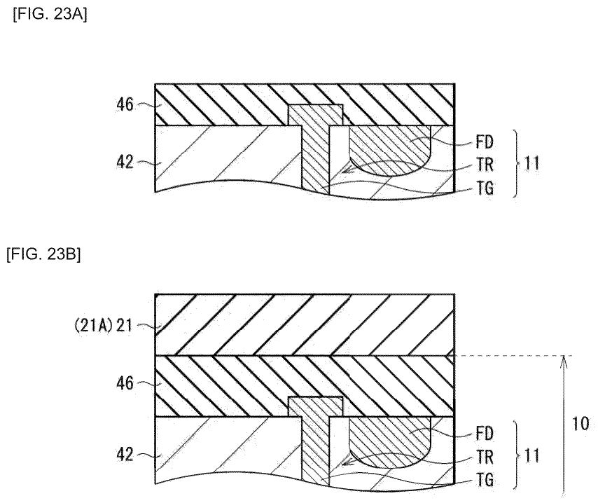

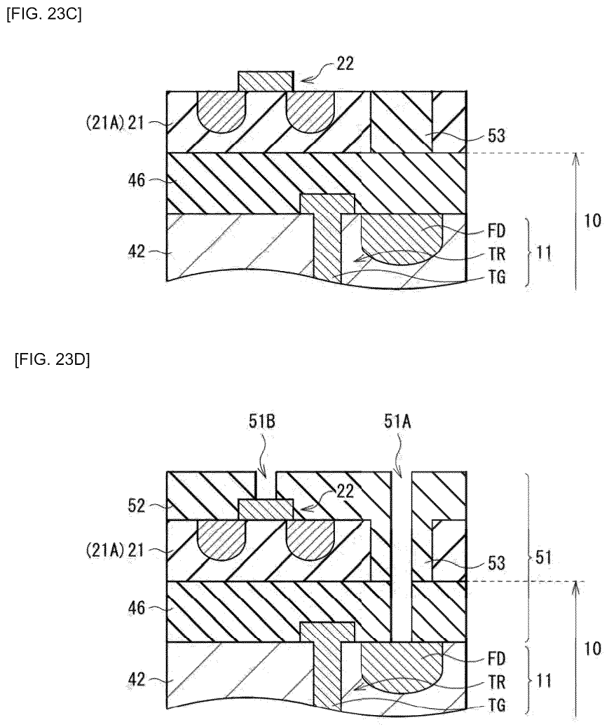

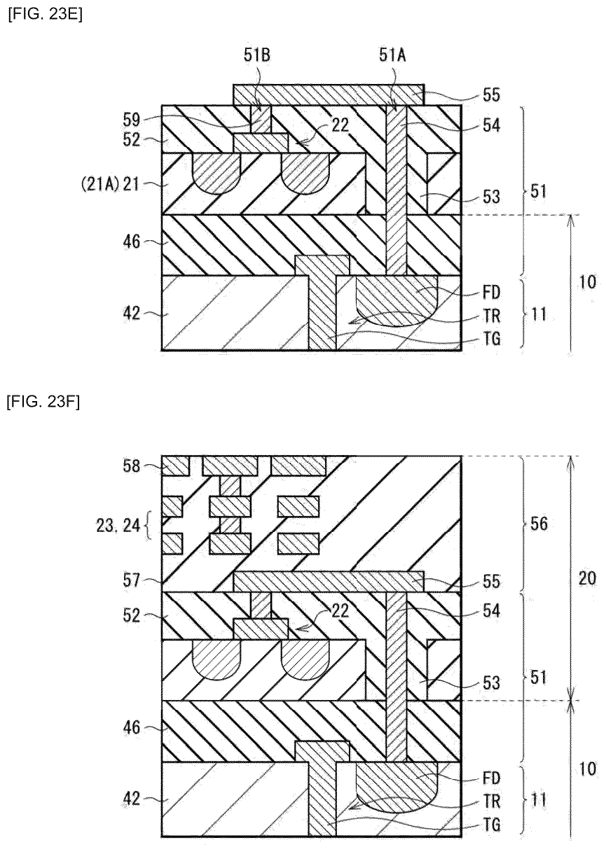

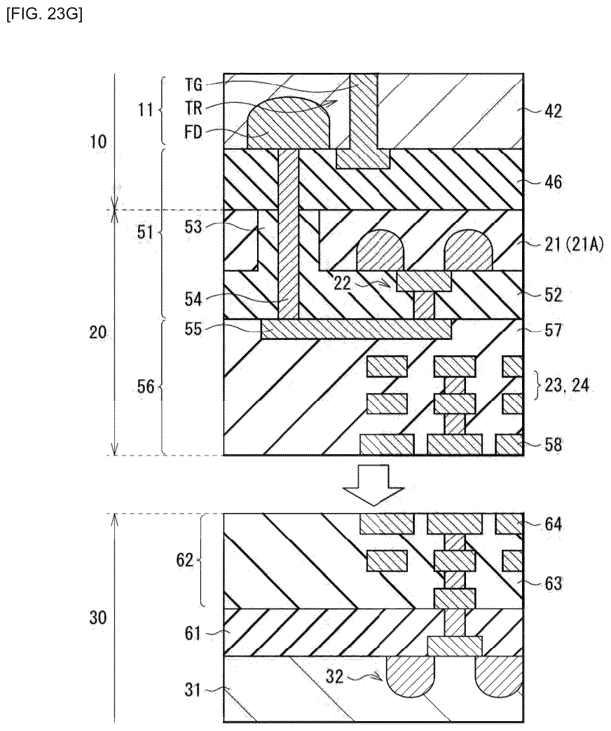

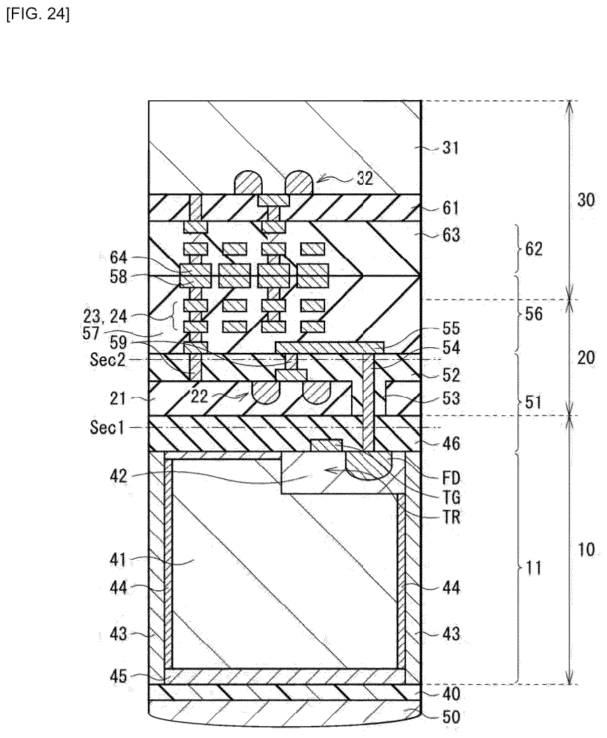

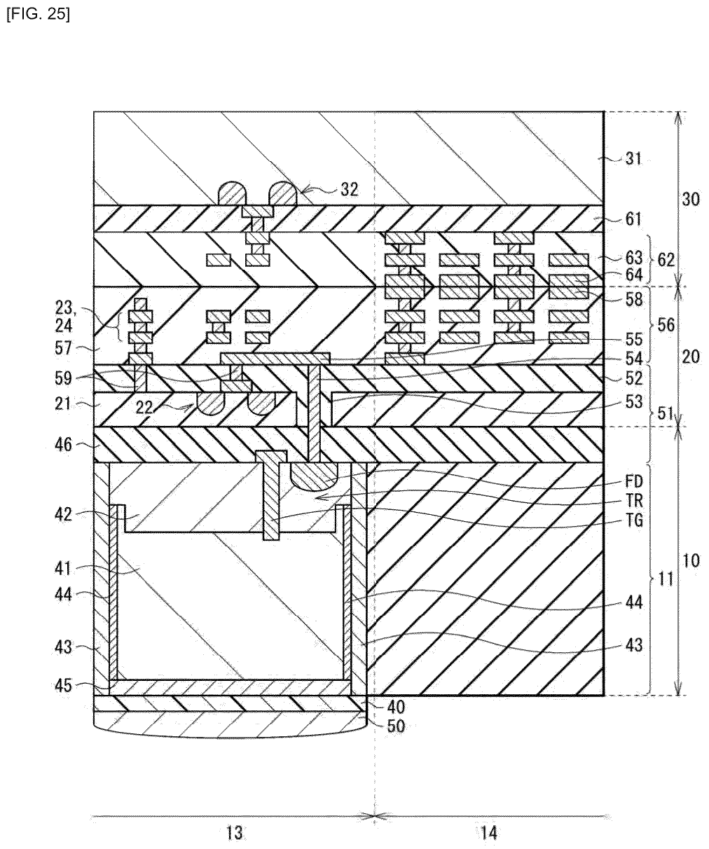

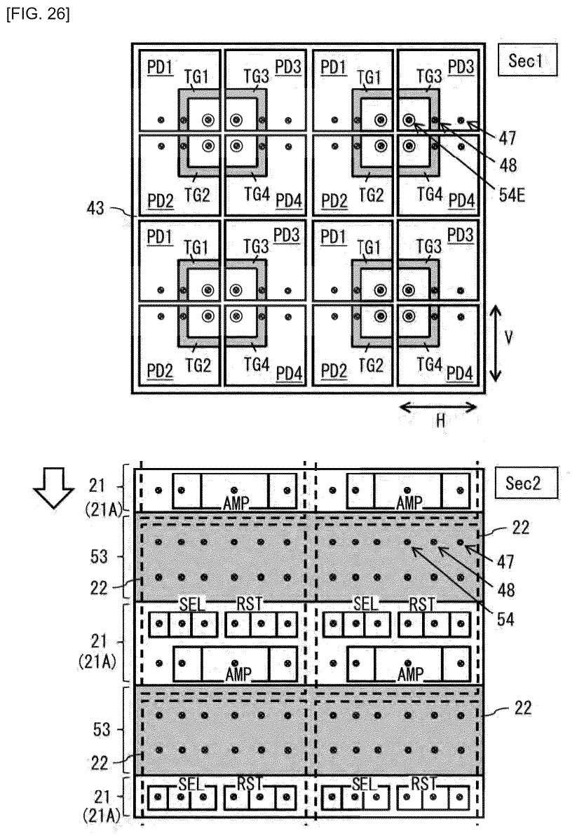

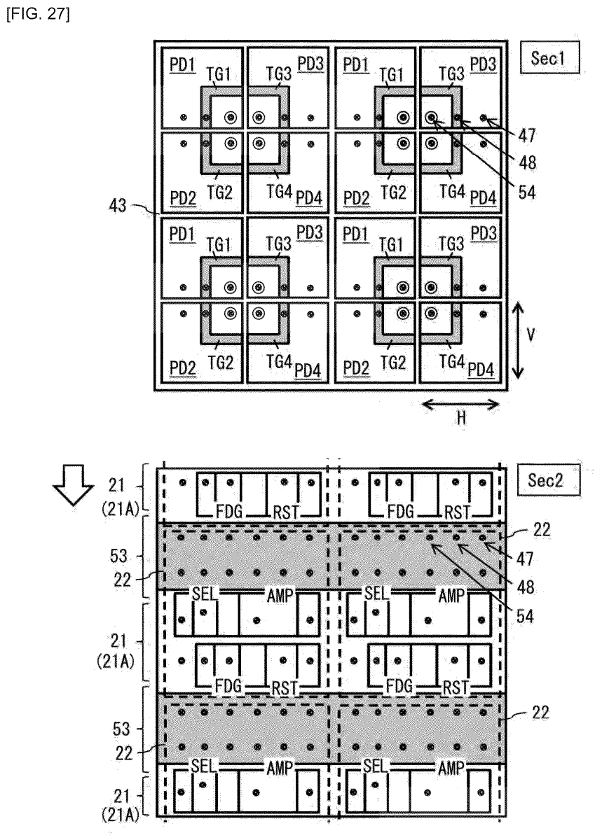

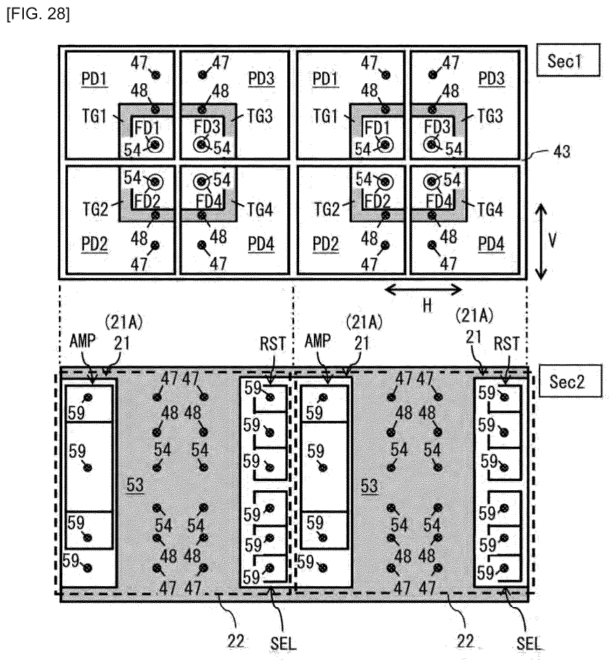

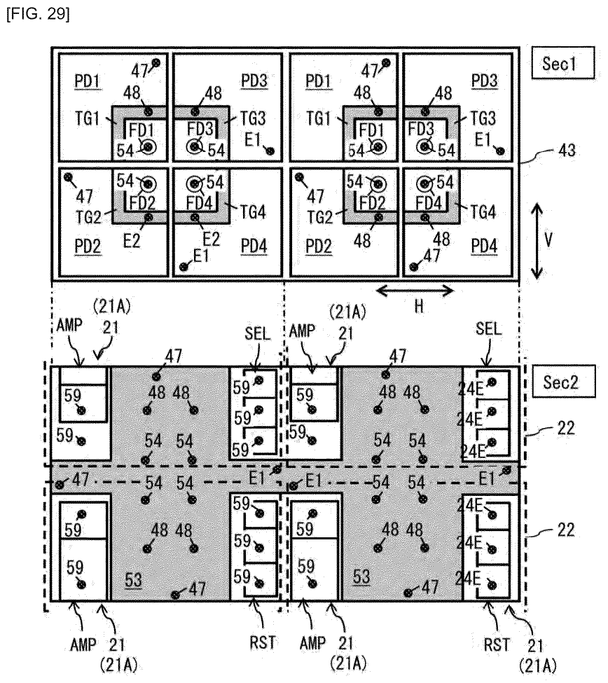

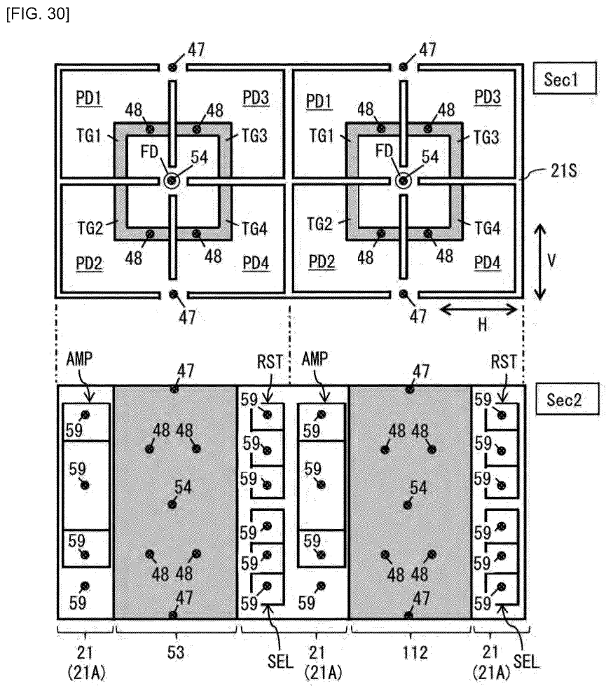

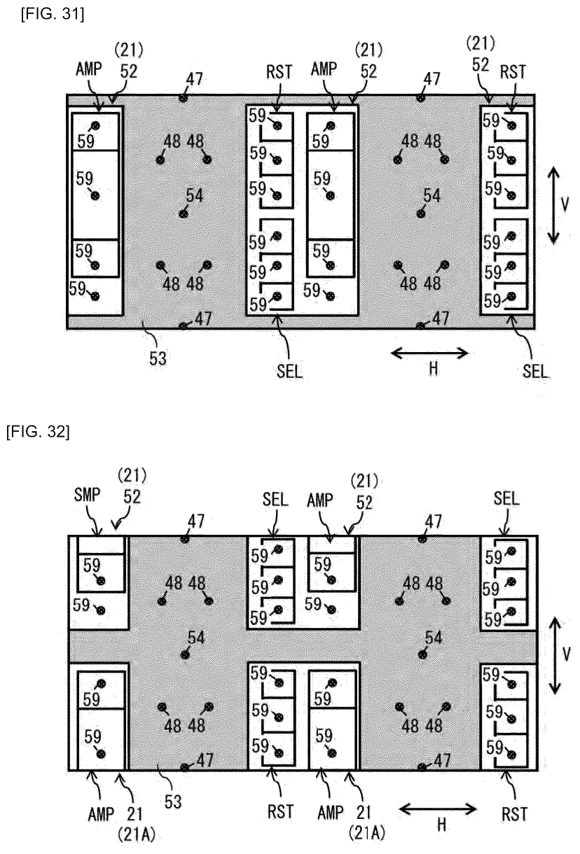

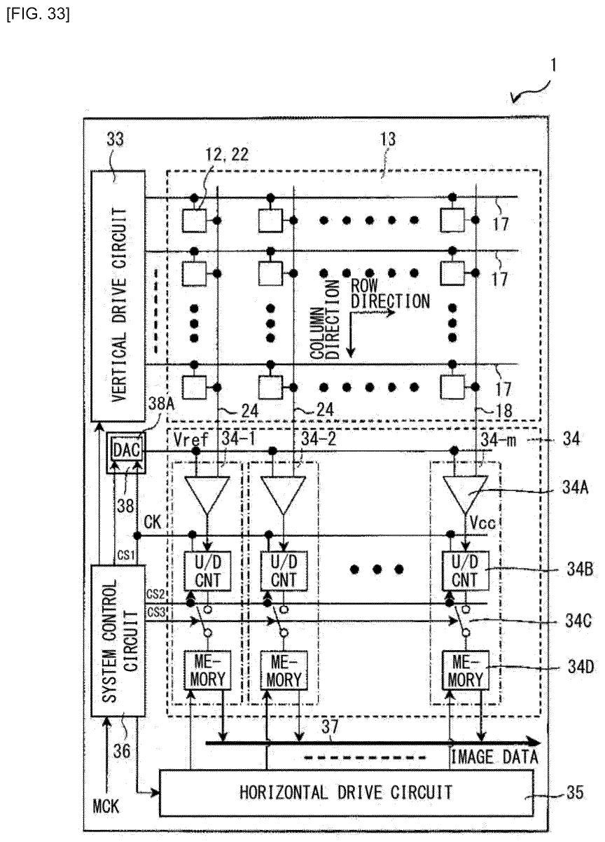

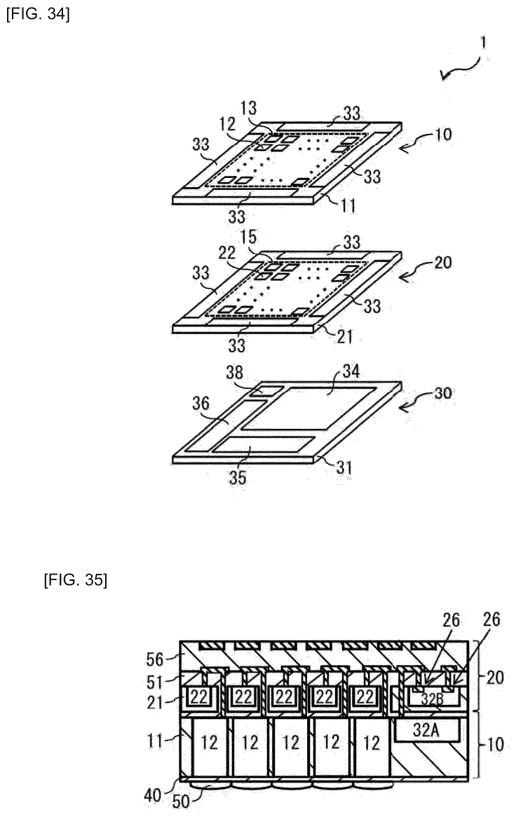

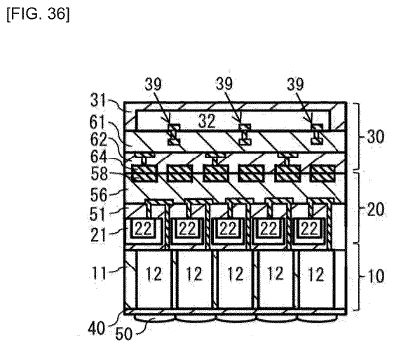

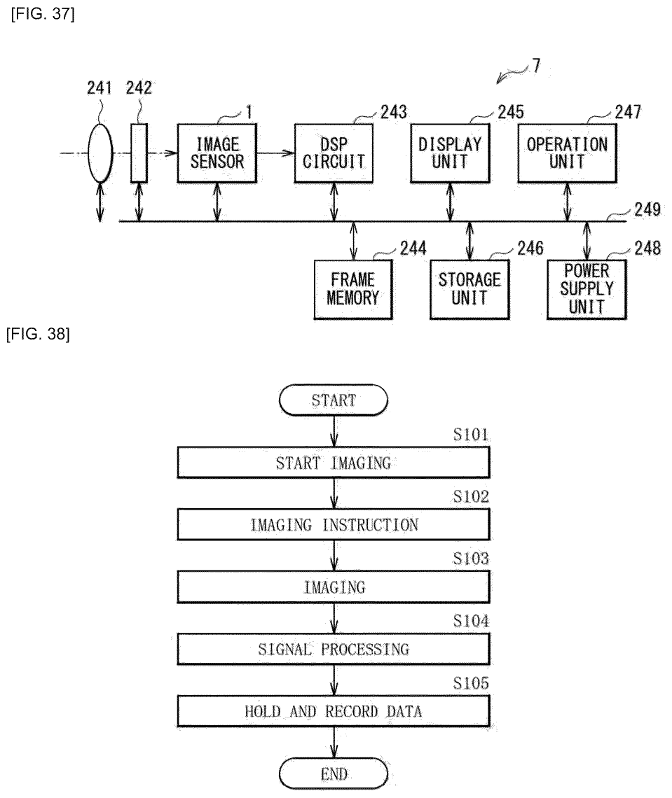

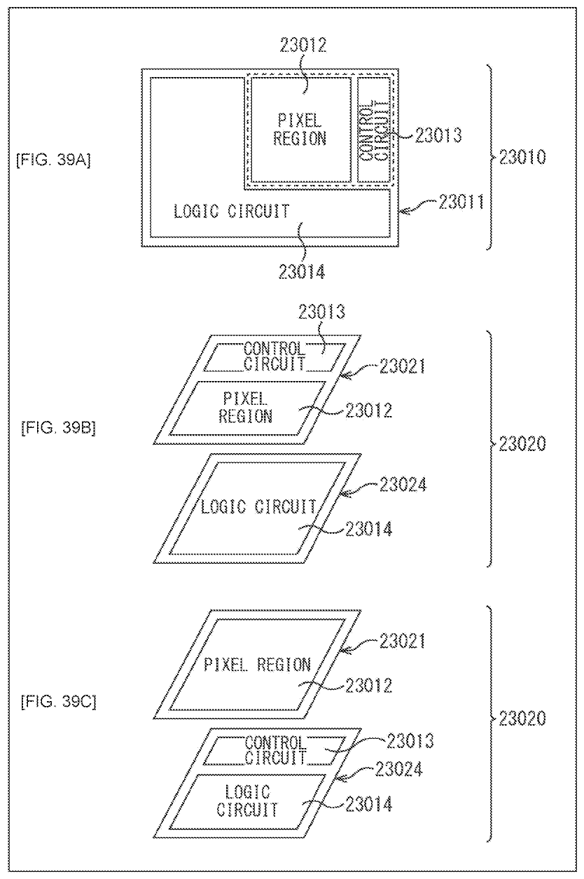

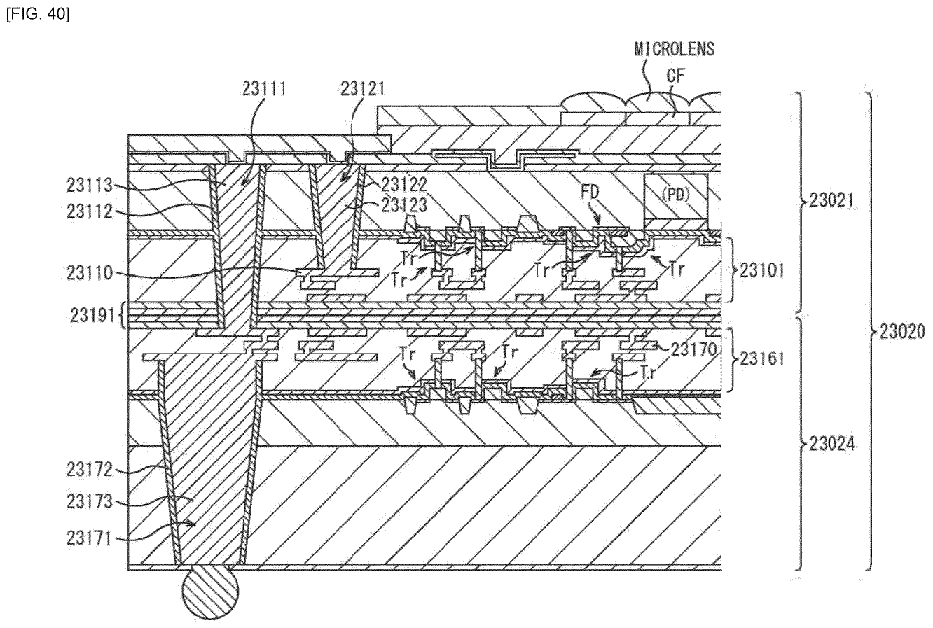

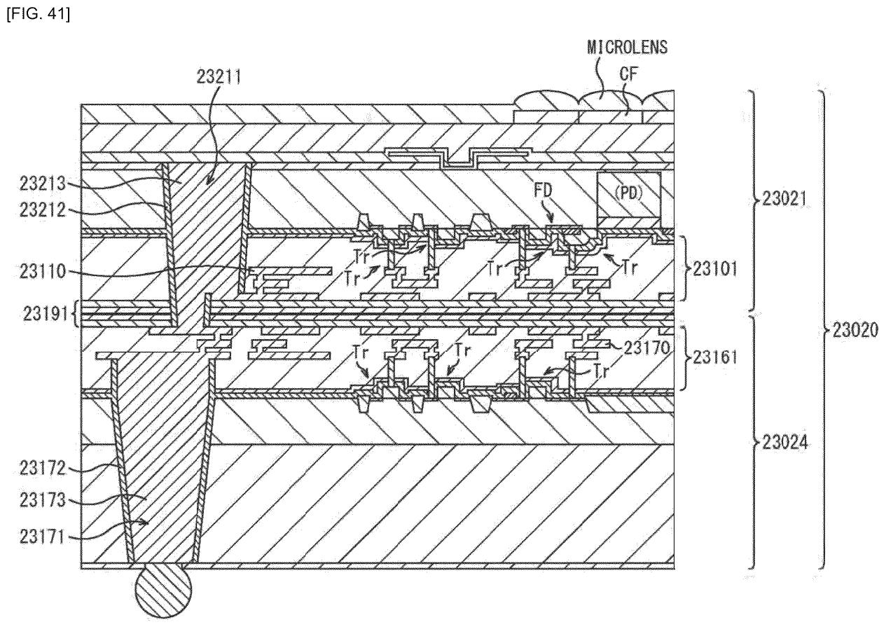

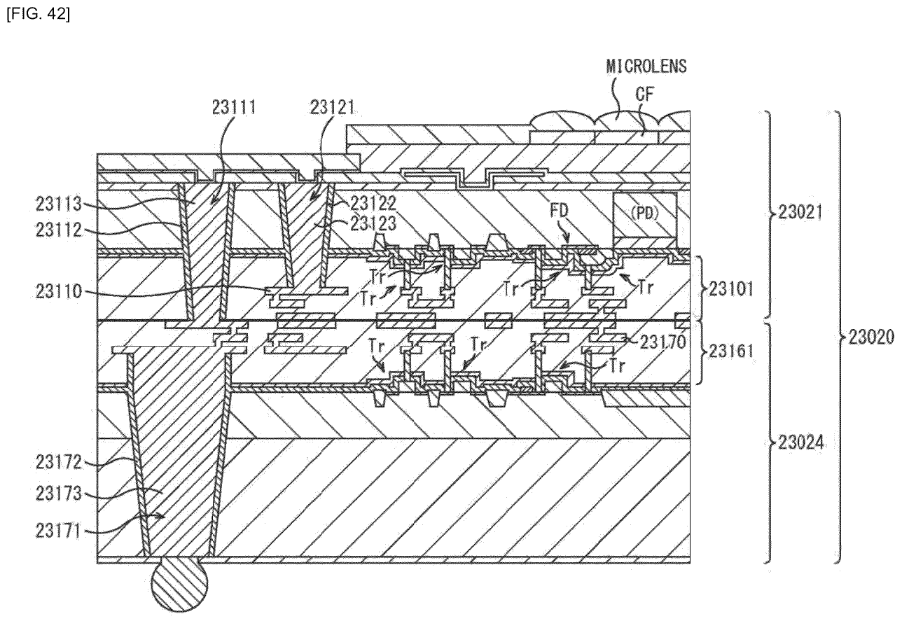

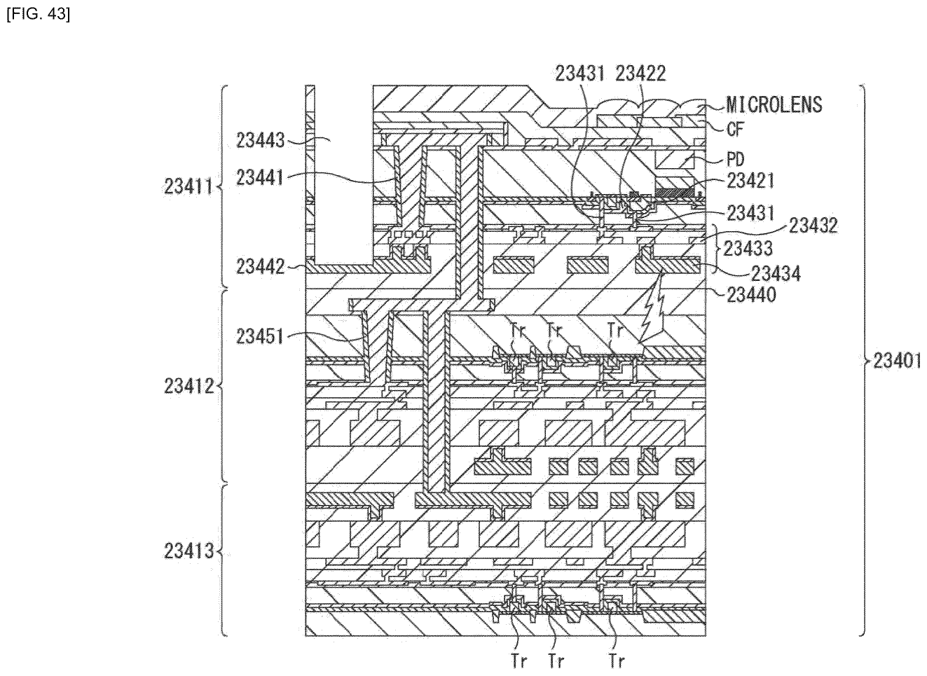

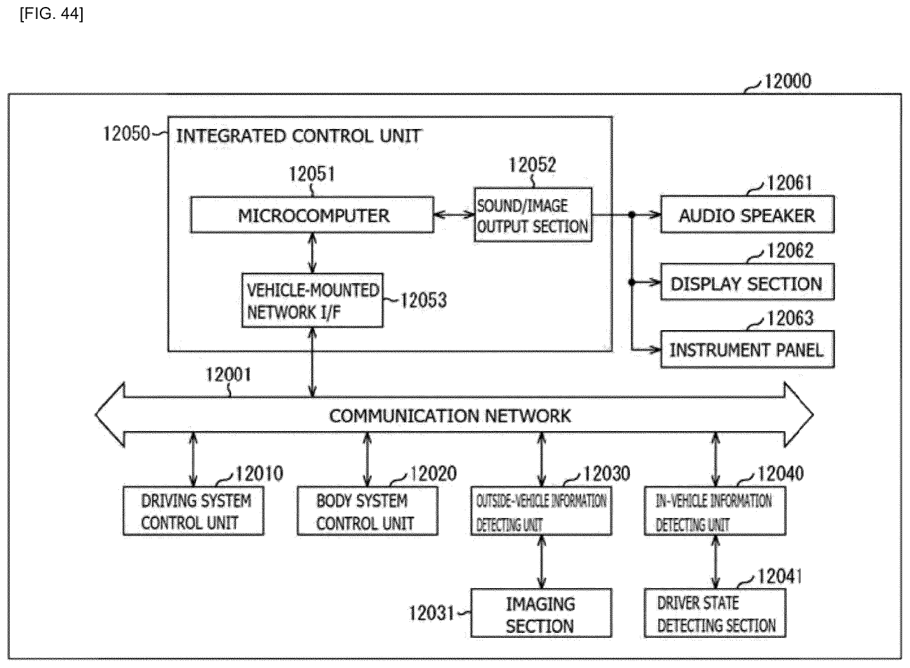

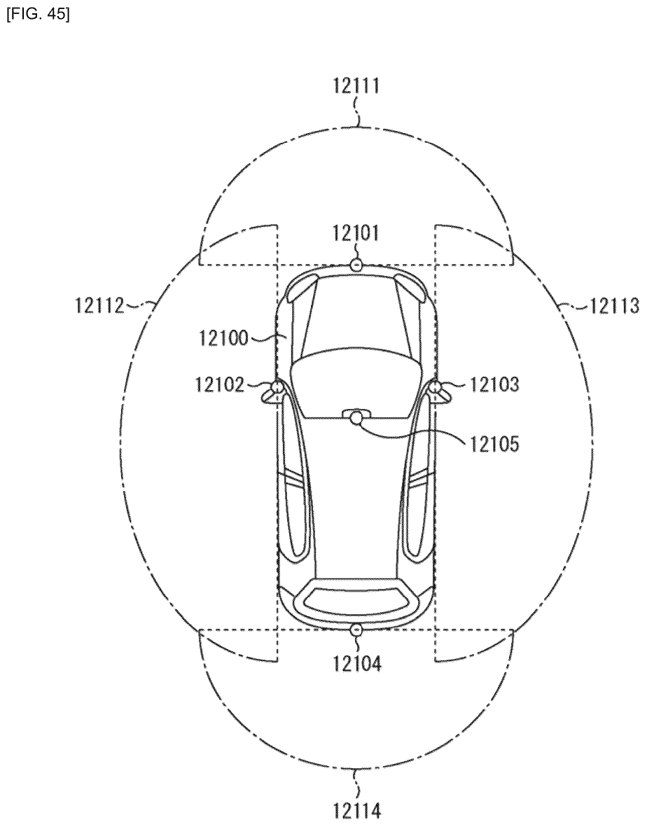

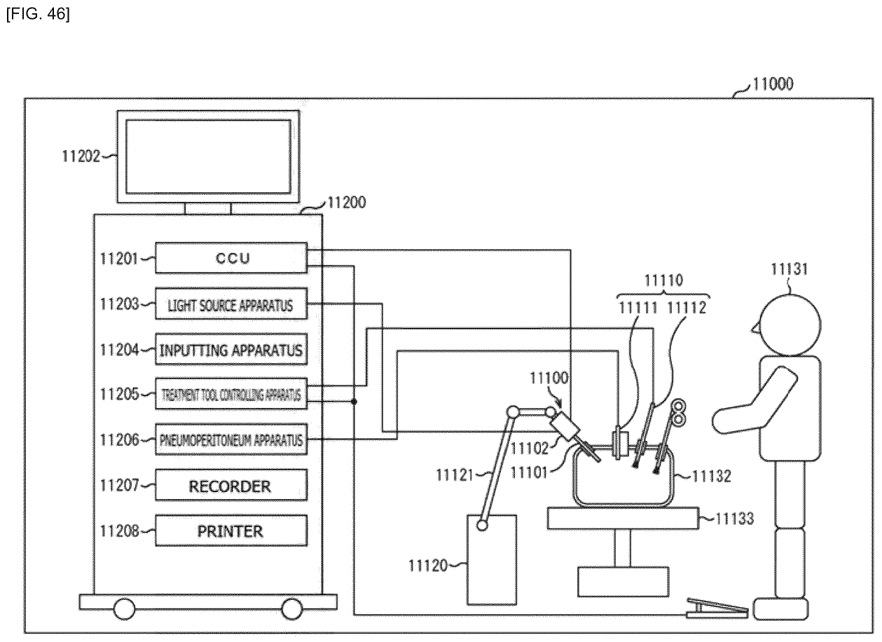

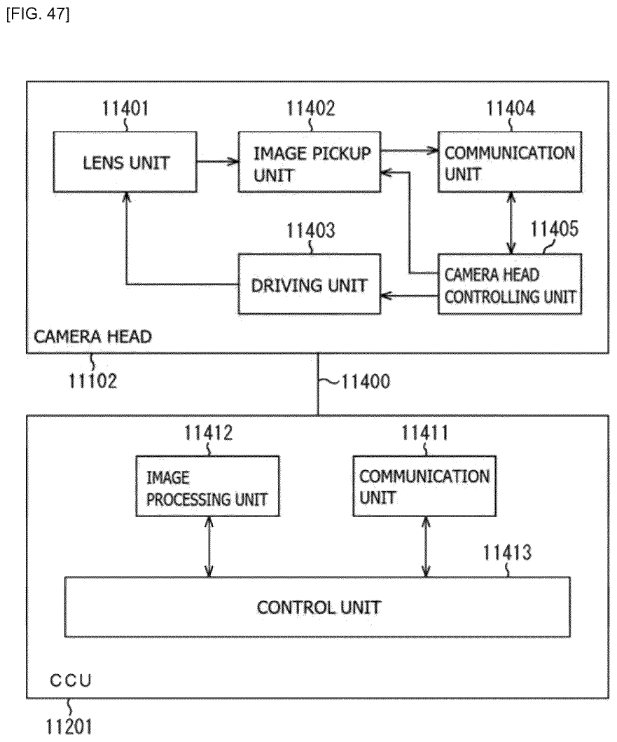

Then, as illustrated in FIG. 5H, the barrier metal 134A is formed on the SiO film 135 and the side surfaces and bottom surfaces of the openings 133H1, 133H2, and 133H3, for example, by means of a sputter, and after that, the metal film 134B is formed inside the openings 133H1, 133H2, and 133H3, for example, by means of plating. After that, the barrier metal 134A and the metal film 134B formed on the SiO film 135, the SiO film 135, and the insulating layer 133 are ground. Thus, as illustrated in FIG. 51, the third layer 130 with the conducting films 134X and 134Y having different thicknesses from each other embedded in the surface of the insulating layer 133 is formed. After that, the insulating layer 141 is formed, for example, by using the CVD method. Through the above process, the wiring structure 100 illustrated in FIG. 1 is completed.

It is noted that in the above-described method, there is given an example where as a film having a different etching rate from the insulating layer 133, the SiO film 135 is formed on the insulating layer 133; however, the method is not limited to this. A film to be formed on the insulating layer 133 only has to differ in the etching rate from the insulating layer 133. A difference in the etching rate is caused, for example, by using a difference between material compositions (a material containing an element that is not contained in the insulating layer 133). As an example, an SiC film, an SiCN film, an SiN film, an AlN film, an AlO film, or an AlON film may be used instead of the SiO film 135.

As above, the wiring structure 100 and its manufacturing method of the present embodiment have been described with FIGS. 1 to 4 and 5A to 51; however, a structure of each part of the wiring structure 100 and its manufacturing method are not limited to those. For example, by stacking multiple films having different etching rates from one another on the insulating layer 133, it becomes possible to further increase the difference in depth between the openings 133H1 and 133H2. Below is described a manufacturing method in a case where multiple films having different etching rates from one another are stacked on the insulating layer 133.

First, for the purpose of reducing the step height on the surface of the insulating layer 133, as illustrated in FIG. 6A, the SiO film 135 having a film thickness of, for example, 100 nm to 1000 nm is formed on the insulating layer 133, for example, by using the CVD method, as with the above. Next, as illustrated in FIG. 6A, an SiCN film 136 having a film thickness of, for example, 100 nm to 1000 nm is further formed on the SiO film 135. Then, as illustrated in FIG. 6B, the SiCN film 136 is polished, for example, by using the CMP method to planarize a surface of the SiCN film 136.

Next, as illustrated in FIGS. 6C to 6E, the openings 133H1 and 133H2 are formed in the air-gaps-forming region 100X and the other regions, respectively, for example, by dry etching. At this time, by selecting an etching condition that the etching rate becomes higher in the order of the SiCN film 136 <the SiO film 135 <the insulating layer 133, the difference in depth between the opening 133H1 in the air-gaps-forming region 100X and the openings 133H2 becomes greater than that is in the above-described method. After that, as illustrated in FIG. 6E, the opening 133H3 that reaches the wire 123X1 is formed within the opening 133H2 by using a similar method.

Then, as illustrated in FIG. 6F, the barrier metal 134A is formed on the SiCN film 136 and the side surfaces and bottom surfaces of the openings 133H1, 133H2, and 133H3, for example, by means of a sputter, and after that, the metal film 134B is formed inside the openings 133H1, 133H2, and 133H3, for example, by means of plating. After that, the barrier metal 134A and the metal film 134B formed on the SiCN film 136, the SiCN film 136, the SiO film 135, and the insulating layer 133 are ground. Thus, as illustrated in FIG. 6G, the third layer 130 with the conducting films 134X and 134Y having a greater difference in thickness embedded in the surface of the insulating layer 133 is formed.

Furthermore, FIG. 1 illustrates an example where the depth of the opening 122H3 with the air gaps G formed is substantially the same depth as the respective bottom surfaces of the wires 123X1 to 123X5 and 123Y1 and 123Y2 included in the wiring layer 123; however, it is not limited to this. For example, as illustrated in FIG. 7, the depth of the opening 122H3 in which air gaps G are formed may be shallower than the bottom surfaces of the wires 123X1 to 123X5 and 123Y1 and 123Y2. Alternatively, the depth of the opening 122H3 with air gaps G formed may be deeper than the bottom surfaces of the wires 123X1 to 123X5 and 123Y1 and 123Y2.

Furthermore, as illustrated in FIG. 8, for example, upper surfaces of the wires 123X2 to 123X5, which are exposed, for example, from the insulating layer 131 and air gaps are formed, for example, in their side surface direction, may be depressed from upper surfaces of the other wires 123X1, 123Y1, and 123Y2.

### 1-3. Configuration of Image Sensor

FIG. 9 illustrates an example of a vertical cross-sectional configuration of an image sensor (the image sensor 1) according to an embodiment of the present disclosure. FIG. 10 illustrates an example of a schematic configuration of the image sensor 1 illustrated in

FIG. 9. The image sensor 1 is an image sensor having a three-dimensional structure in which a first substrate 10, a second substrate 20, and a third substrate 30 are stacked on top of another. The first substrate 10 includes sensor pixels 12 on a semiconductor substrate 11: the sensor pixels 12 perform photoelectric conversion. The second substrate 20 includes readout circuits 22 on a semiconductor substrate 21: the readout circuits 22 each output an image signal based on electric charges output from the sensor pixels 12. The third substrate 30 includes a logic circuit 32 on a semiconductor substrate 31: the logic circuit 32 processes a pixel signal. As illustrated in FIG. 11, the above-described wiring structure 100 is applied to, for example, a wiring structure near a junction surface of the second substrate 20 joined to the third substrate 30.

As described above, the first substrate 10 includes, on the semiconductor substrate 11, the multiple sensor pixels 12 that perform photoelectric conversion. The multiple sensor pixels 12 are provided in a matrix within a pixel region 13 of the first substrate 10. The second substrate 20 includes, on the semiconductor substrate 21, the readout circuits 22, one for every four sensor pixels 12: the readout circuits 22 output a pixel signal based on electric charges output from the corresponding sensor pixels 12. The second substrate 20 includes multiple pixel drive wires 23 extending in a row direction and multiple vertical signal wires 24 extending in a column direction. The third substrate 30 includes, on the semiconductor substrate 31, the logic circuit 32 that processes a pixel signal. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout with respect to each sensor pixel 12 to the outside. The logic circuit 32 may be formed with, for example, a low-resistance region including silicide such as CoSi₂ or NiSi formed using a self-aligned silicide process on a surface of an impurity diffusion region in contact with a source electrode and a drain electrode. In the present embodiment, the semiconductor substrate 11 corresponds to a specific example of a “first semiconductor substrate” of the present disclosure, and the first substrate 10 corresponds to a specific example of a “first substrate” of the present disclosure. The semiconductor substrate 31 corresponds to a specific example of a “second semiconductor substrate” of the present disclosure, and the third substrate 30 corresponds to a specific example of a “second substrate” of the present disclosure. It is noted that the second substrate 20 including the semiconductor substrate 21 is able to be regarded as those included in the “first substrate” side and the “second substrate” side of the present disclosure.

The vertical drive circuit 33 sequentially selects, for example, multiple sensor pixels 12 by the row. For example, the column signal processing circuit 34 performs a correlated double sampling (CDS) process on a pixel signal output from each of sensor pixels 12 in a row selected by the vertical drive circuit 33. For example, by performing the CDS process, the column signal processing circuit 34 extracts a signal level of the pixel signal, and holds pixel data in accordance with an amount of light received by each sensor pixel 12. For example, the horizontal drive circuit 35 sequentially outputs the pixel data held in the column signal processing circuit 34 to the outside. For example, the system control circuit 36 controls driving of each of blocks (the vertical drive circuit 33, the column signal processing circuit 34, and the horizontal drive circuit 35) in the logic circuit 32.

FIG. 12 illustrates an example of the sensor pixels 12 and the readout circuit 22. Below is described a case where four sensor pixels 12 share one readout circuit 22 as illustrated in FIG. 12. The term “share” here means outputs of four sensor pixels 12 are input to a shared readout circuit 22.

The sensor pixels 12 include components common to one another. In FIG. 12, to distinguish respective components of the sensor pixels 12 from one another, an identification number (1, 2, 3, or 4) is added to the end of a code of a component of each sensor pixel 12. In the following, in a case where it is necessary to distinguish the respective components of the sensor pixels 12 from one another, the identification number is added to the end of a code of a component of each sensor pixel 12; however, in a case where it is not necessary to distinguish the respective components of the sensor pixels 12 from one another, the identification number in the end of a code of a component of each sensor pixel 12 is omitted.

Each sensor pixel 12 includes, for example, a photodiode PD, a transfer transistor TR electrically coupled to the photodiode PD, and a floating diffusion FD that temporarily holds an electric charge output from the photodiode PD through the transfer transistor TR. The photodiode PD performs photoelectric conversion and generates an electric charge in accordance with an amount of received light. A cathode of the photodiode PD is electrically coupled to a source of the transfer transistor TR, and an anode of the photodiode PD is electrically coupled to a reference potential line (for example, the ground). A drain of the transfer transistor TR is electrically coupled to the floating diffusion FD, and a gate of the transfer transistor TR is electrically coupled to the pixel drive wires 23. The transfer transistor TR is, for example, a CMOS (complementary metal oxide semiconductor) transistor.

The respective floating diffusions FD of the sensor pixels 12 that share one readout circuit 22 are electrically coupled to one another, and are electrically coupled to an input terminal of the shared readout circuit 22. The readout circuit 22 includes, for example, a reset transistor RST, a selection transistor SEL, and an amplification transistor AMP. It is noted that the selection transistor SEL may be omitted as necessary. A source of the reset transistor RST (the input terminal of the readout circuit 22) is electrically coupled to the floating diffusions FD, and a drain of the reset transistor RST is electrically coupled to a power wire VDD and a drain of the amplification transistor AMP. A gate of the reset transistor RST is electrically coupled to the pixel drive wires 23. A source of the amplification transistor AMP is electrically coupled to a drain of the selection transistor SEL, and a gate of the amplification transistor AMP is electrically coupled to the source of the reset transistor RST. A source of the selection transistor SEL (an output terminal of the readout circuit 22) is electrically coupled to the vertical signal wires 24, and a gate of the selection transistor SEL is electrically coupled to the pixel drive wires 23.

When the transfer transistor TR falls into on-state, the transfer transistor TR transfers an electric charge of the photodiode PD to the floating diffusion FD. The gate (a transfer gate TG) of the transfer transistor TR extends, for example, as illustrated in FIG. 9, from a surface of the semiconductor substrate 11 up to a depth that reaches a PD 41 going through a p-well 42. The reset transistor RST resets the potential of the floating diffusion FD to a predetermined potential. When the reset transistor RST falls into on-state, the potential of the floating diffusion FD is reset to the potential of the power wire VDD. The selection transistor SEL controls the timing to output a pixel signal from the readout circuit 22. The amplification transistor AMP generates, as a pixel signal, a signal of a voltage in accordance with the level of an electric charge held in the floating diffusion FD. The amplification transistor AMP includes a source-follower amplifier, and outputs a pixel signal of a voltage in accordance with the level of an electric charge generated in the photodiode PD. When selection transistor SEL falls into on-state, the amplification transistor AMP amplifies the potential of the floating diffusion FD, and outputs a voltage in accordance with that potential to the column signal processing circuit 34 through the vertical signal wires 24. The reset transistor RST, the amplification transistor AMP, and the selection transistor SEL are, for example, a CMOS transistor.

It is noted that as illustrated in FIG. 13, the selection transistor SEL may be provided between the power wire VDD and the amplification transistor AMP. In this case, the drain of the reset transistor RST is electrically coupled to the power wire VDD and the drain of the selection transistor SEL. The source of the selection transistor SEL is electrically coupled to the drain of the amplification transistor AMP, and the gate of the selection transistor SEL is electrically coupled to the pixel drive wires 23. The source of the amplification transistor AMP (the output terminal of the readout circuit 22) is electrically coupled to the vertical signal wires 24, and the gate of the amplification transistor AMP is electrically coupled to the source of the reset transistor RST. Furthermore, as illustrated in FIGS. 14 and 15, an FD transfer transistor FDG may be provided between the source of the reset transistor RST and the gate of the amplification transistor AMP.

The FD transfer transistor FDG is used when the conversion efficiency is switched. In general, a pixel signal is low at the time of taking a picture in a dark place. When charge-to-voltage conversion is performed on the basis of Q=CV, if the capacitance of the floating diffusion FD (the FD capacitance C) is large, V when the amplification transistor AMP has converted an electric charge into a voltage becomes small. Meanwhile, in a bright place, a pixel signal becomes high: therefore, if the FD capacitance C is not large, the floating diffusion FD is not enough to receive an electric charge of the photodiode PD. Furthermore, it is necessary for the FD capacitance C to be large enough to cause V not to become too large (in other words, to become small) when the amplification transistor AMP has converted an electric charge into a voltage. On the basis of these, when the FD transfer transistor FDG is turned on, the gate capacitance for the FD transfer transistor FDG is increased, thus the overall FD capacitance C becomes small. By switching the FD transfer transistor FDG on and off in this way, it becomes possible to make the FD capacitance C variable and switch the conversion efficiency.

FIG. 16 illustrates an example of a coupling form of the multiple readout circuits 22 and the multiple vertical signal wires 24. In a case where the multiple readout circuits 22 are disposed to be aligned in an extending direction of the vertical signal wires 24 (for example, the column direction), the multiple vertical signal wires 24, one for each readout circuit 22, may be assigned. For example, in a case where four readout circuits 22 are disposed to be aligned in the extending direction of the vertical signal wires 24 (for example, the column direction) as illustrated in FIG. 16, four vertical signal wires 24, one for each readout circuit 22, may be assigned. It is noted that in FIG. 16, to distinguish the respective vertical signal wires 24 from one another, an identification number (1, 2, 3, or 4) is added to the end of a code of each vertical signal wire 24.

Subsequently, a vertical cross-sectional configuration of the image sensor 1 is described with FIG. 9. As described above, the image sensor 1 has a configuration in which the first substrate 10, the second substrate 20, and the third substrate 30 are stacked on top of another in this order, and further includes a color filter 40 and a light receiving lens 50 on the side of a back surface (a light incident surface) of the first substrate 10. The color filter 40 and the light receiving lens 50 are each provided, for example, one for each sensor pixel 12. That is, the image sensor 1 is a back-illuminated image sensor.

The first substrate 10 includes an insulating layer 46 stacked on the surface (a surface 11S1) of the semiconductor substrate 11. The first substrate 10 includes the insulating layer 46 as part of an interlayer insulating film 51. The insulating layer 46 is provided between the semiconductor substrate 11 and the semiconductor substrate 21 to be described later. The semiconductor substrate 11 includes a silicon substrate. The semiconductor substrate 11 includes, for example, in a portion of the surface and its surroundings, the p-well 42 and, in the other region (a region deeper than the p-well 42), the PD 41 of a different conductivity type from the p-well 42. The p-well 42 includes a p-type semiconductor region. The PD 41 includes a semiconductor region of a different conductivity type from the p-well 42 (specifically, n-type). The semiconductor substrate 11 includes, within the p-well 42, the floating diffusion FD as the semiconductor region of the different conductivity type from the p-well 42 (specifically, n-type).

The first substrate 10 includes, with respect to each sensor pixel 12, the photodiode PD, the transfer transistor TR, and the floating diffusion FD. The first substrate 10 is provided with the transfer transistor TR and the floating diffusion FD in a portion of the semiconductor substrate 11 on the surface 11S1 side (the side opposite to the light incident side, the second substrate 20 side). The first substrate 10 includes an isolation part 43 that isolates each sensor pixel 12. The isolation part 43 is formed to extend in a normal direction (a direction perpendicular to the surface of the semiconductor substrate 11) of the semiconductor substrate 11. The isolation part 43 is provided between two sensor pixels 12 adjacent to each other. The isolation part 43 electrically isolates the sensor pixels 12 adjacent to each other. The isolation part 43 includes, for example, silicon oxide. For example, the isolation part 43 goes through the semiconductor substrate 11. The first substrate 10 further includes, for example, a p-well layer 44 in contact with a side surface of the isolation part 43 that is a photodiode-PD-side surface. The p-well layer 44 includes a semiconductor region of a different conductivity type from the photodiode PD (specifically, p-type). For example, the first substrate 10 further includes a fixed charge film 45 in contact with a back surface (a surface 11S2, another surface) of the semiconductor substrate 11. The fixed charge film 45 is negatively charged to suppress the generation of dark current caused by an interface state on the side of a light receiving surface of the semiconductor substrate 11. The fixed charge film 45 is formed of, for example, an insulating film having a negative fixed charge. Examples of a material of such an insulating film include hafnium oxide, zirconium oxide, aluminum oxide, titanium oxide, and tantalum oxide. A hole accumulation layer is formed on an interface on the side of the light receiving surface of the semiconductor substrate 11 by an electric field induced by the fixed charge film 45. The generation of electrons from the interface is suppressed by this hole accumulation layer. The color filter 40 is provided, for example, in contact with the fixed charge film 45, and is provided in a position opposed to the sensor pixel 12 through the fixed charge film 45. The light receiving lens 50 is provided, for example, in contact with the color filter 40, and is provided in a position opposed to the sensor pixel 12 through the color filter 40 and the fixed charge film 45.

The second substrate 20 includes an insulating layer 52 stacked on the semiconductor substrate 21. The second substrate 20 includes the insulating layer 52 as part of the interlayer insulating film 51. The insulating layer 52 is provided between the semiconductor substrate 21 and the semiconductor substrate 31. The semiconductor substrate 21 includes a silicon substrate. The second substrate 20 includes the readout circuits 22, one for every four sensor pixels 12. The second substrate 20 has a configuration in which the readout circuits 22 are provided on a portion of the semiconductor substrate 21 on the side of the surface (a surface 21S1 opposed to the third substrate 30, one surface). The second substrate 20 is bonded to the first substrate 10 with a back surface (a surface 21S2) of the semiconductor substrate 21 opposed to the surface (the surface 11S1) of the semiconductor substrate 11. That is, the second substrate 20 is bonded to the first substrate 10 face-to-back. The second substrate 20 further includes, within the same layer as the semiconductor substrate 21, an insulating layer 53 going through the semiconductor substrate 21. The second substrate 20 includes the insulating layer 53 as part of the interlayer insulating film 51. The insulating layer 53 is provided to cover a side surface of a through-wire 54 to be described later.

A stacked body including the first and second substrates 10 and 20 includes the interlayer insulating film 51 and the through-wire 54 provided in the interlayer insulating film 51. The above-described stacked body includes one through-wire 54 for each sensor pixel 12. The through-wire 54 extends in the normal direction of the semiconductor substrate 21, and is provided to go through, within the interlayer insulating film 51, a portion including the insulating layer 53. The first and second substrates 10 and 20 are electrically coupled to each other by the through-wire 54. Specifically, the through-wire 54 is electrically coupled to the floating diffusion FD and a coupling wire 55 to be described later.

The stacked body including the first and second substrates 10 and 20 further includes through-wires 47 and 48 provided in the interlayer insulating film 51 (see FIG. 17 to be described later). The above-described stacked body includes one through-wire 47 and one through-wire 48 for each sensor pixel 12. The through-wires 47 and 48 each extend in the normal direction of the semiconductor substrate 21, and are provided to go through, within the interlayer insulating film 51, a portion including the insulating layer 53. The first and second substrates 10 and 20 are electrically coupled to each other by the through-wires 47 and 48. Specifically, the through-wire 47 is electrically coupled to the p-well 42 of the semiconductor substrate 11 and a wire in the second substrate 20. The through-wire 48 is electrically coupled to the transfer gate TG and the pixel drive wires 23.

The second substrate 20 includes, for example, within the insulating layer 52, multiple coupling parts 59 electrically coupled to the readout circuits 22 and the semiconductor substrate 21. The second substrate 20 further includes, for example, a wiring layer 56 on the insulating layer 52. The wiring layer 56 includes, for example, an insulating layer 57, and the multiple pixel drive wires 23 and the multiple vertical signal wires 24 provided in the insulating layer 57. The wiring layer 56 further includes, for example, within the insulating layer 57, the multiple coupling wires 55, one for every four sensor pixels 12. The coupling wires 55 are electrically coupled to the respective through-wires 54 electrically coupled to the floating diffusions FD included in the four sensor pixels 12 sharing the readout circuit 22. Here, the total number of the through-wires 54 and 48 is greater than the total number of the sensor pixels 12 included in the first substrate 10, and is twice the total number of the sensor pixels 12 included in the first substrate 10. Furthermore, the total number of the through-wires 54, 48, and 47 is greater than the total number of the sensor pixels 12 included in the first substrate 10, and is three times the total number of the sensor pixels 12 included in the first substrate 10.

The wiring layer 56 further includes, for example, within the insulating layer 57, multiple pad electrodes 58. Each pad electrode 58 is formed of, for example, metal such as Cu (copper), tungsten (W), or Al (aluminum). Each pad electrode 58 is exposed on a surface of the wiring layer 56. The respective pad electrodes 58 are used for electrical coupling of the second substrate 20 and the third substrate 30 and bonding of the second substrate 20 and the third substrate 30. The multiple pad electrodes 58 are provided, for example, one pad electrode for each set of the pixel drive wire 23 and the vertical signal wire 24. Here, the total number of the pad electrodes 58 or the total number of junctions of the pad electrodes 58 and pad electrodes 64 (to be described later) is, for example, smaller than the total number of the sensor pixels 12 included in the first substrate 10.

FIG. 11 schematically illustrates a cross-sectional configuration of the image sensor 1 to which the above-described wiring structure 100 is applied. In the present embodiment, for example, the multiple vertical signal wires 24 correspond to wires 112X3 and 112X4 in the above-described wiring structure 100, and a power wire VSS corresponds to wires 112X2 and 112X5 in the above-described wiring structure 100. Although not illustrated in FIG. 9, the insulating layer 57 includes multiple insulating layers 122 and 131 to 133 as illustrated in FIG. 11. By, of those insulating layers, the insulating layer 133, air gaps G are formed between the power wire VSS and the vertical signal wire 24 that run parallel to each other and between the multiple vertical signal wires 24. Each of the pad electrodes 58 (58X1 and 58X2) exposed on the surface of the wiring layer 56 corresponds to the conducting film 134X, 134Y, or 134Z in the above-described wiring structure 100.

Some (the pad electrode 58X1) of the pad electrodes 58 are electrically coupled to a ground wire (a wire 112X1). Although not illustrated, the ground wire is coupled, for example, to a p-well and the ground (GND) of the semiconductor substrate 11. Thus, the pad electrode 58X1 is able to be used as a shield wire with respect to the stacking direction of the vertical signal wires 24, and makes it possible to reduce the generation of noise in the vertical signal wires 24.

Furthermore, the pad electrode 58X1 serving as a shield wire is joined to a pad electrode 64X1 on the side of the third substrate 30 to be described later. Thus, it becomes possible to lower the impedance of the shield wire as compared with a case where a shield wire is formed by the pad electrode 58X1 alone. Moreover, the pad electrode 58X1 serving as a shield wire is provided, for example, to run through the pixel region 13, as with the vertical signal wires 24, and terminates near the periphery beyond a region end of the pixel region 13.

The third substrate 30 includes, for example, an interlayer insulating film 61 stacked on the semiconductor substrate 31. It is noted that the third substrate 30 is, as described later, bonded to the second substrate 20 face-to-face; therefore, at the time of description of a configuration of the inside of the third substrate 30, description of up and down becomes opposite to an up-down direction in the drawings. The semiconductor substrate 31 includes a silicon substrate. The third substrate 30 has a configuration in which the logic circuit 32 is provided on a portion of the semiconductor substrate 31 on the side of a surface (a surface 31S1). The third substrate 30 further includes, for example, an wiring layer 62 on the interlayer insulating film 61. The wiring layer 62 includes, for example, an insulating layer 63 and the multiple pad electrodes 64 (for example, pad electrodes 64X1 and 64X2) provided in the insulating layer 63. The multiple pad electrodes 64 are electrically coupled to the logic circuit 32. Each pad electrode 64 is formed of, for example, Cu (copper). Each pad electrode 64 is exposed on a surface of the wiring layer 62. The respective pad electrodes 64 are used for electrical coupling of the second substrate 20 and the third substrate 30 and bonding of the second substrate 20 and the third substrate 30. Furthermore, the number of pad electrodes 64 does not necessarily have to be more than one; even one pad electrode 64 enables electrical coupling to the logic circuit 32. The second substrate 20 and the third substrate 30 are electrically coupled to each other by joining of the pad electrodes 58 and 64. That is, the gate (the transfer gate TG) of the transfer transistor TR is electrically coupled to the logic circuit 32 through the through-wires 54 and the pad electrodes 58 and 64. The third substrate 30 is bonded to the second substrate 20 with the surface (the surface 31S1) of the semiconductor substrate 31 opposed to the side of the surface (the surface 21S1) of the semiconductor substrate 21. That is, the third substrate 30 is bonded to the second substrate 20 face-to-face.

FIGS. 17 and 18 illustrate an example of a horizontal cross-sectional configuration of the image sensor 1. The upper diagrams in FIGS. 17 and 18 are diagrams illustrating an example of the cross-sectional configuration of a cross section Sec1 in FIG. 1: the lower diagrams in FIGS. 17 and 18 are diagrams illustrating an example of the cross-sectional configuration of a cross section Sec2 in FIG. 1. FIG. 17 illustrates an example of a configuration in which two sets of four sensor pixels 12 in a 2-by-2 matrix are aligned in a second direction H: FIG. 18 illustrates an example of a configuration in which four sets of four sensor pixels 12 in a 2-by-2 matrix are aligned in a first direction V and the second direction H. It is noted that in the upper parts of the cross-sectional views in FIGS. 17 and 18, a diagram illustrating a surface configuration of the semiconductor substrate 11 is overlaid on the diagram illustrating the example of the cross-sectional configuration of the cross section Sec1 in FIG. 1, and the insulating layer 46 is omitted. Furthermore, in the lower parts of the cross-sectional views in FIGS. 17 and 18, a diagram illustrating a surface configuration of the semiconductor substrate 21 is overlaid on the diagram illustrating the example of the cross-sectional configuration of the cross section Sec2 in FIG. 1.

As illustrated in FIGS. 17 and 18, the multiple through-wires 54, the multiple through-wires 48, and the multiple through-wires 47 are disposed into strips in the first direction V (the up-down direction in FIG. 17, a right-left direction in FIG. 18) within a plane of the first substrate 10. It is noted that FIGS. 17 and 18 illustrate a case where the multiple through-wires 54, the multiple through-wires 48, and the multiple through-wires 47 are disposed in two columns in the first direction V. The first direction V is parallel to, of two array directions (for example, a row direction and a column direction) of the multiple sensor pixels 12 disposed in a matrix, one array direction (for example, the column direction). In four sensor pixels 12 sharing the readout circuit 22, four floating diffusions FD are disposed, for example, close to one another through the isolation part 43. In the four sensor pixels 12 sharing the readout circuit 22, four transfer gates TG are disposed to surround the four floating diffusions FD, and, for example, an annular shape is formed by the four transfer gates TG.

The insulating layer 53 includes multiple blocks extending in the first direction V. The semiconductor substrate 21 includes multiple insular blocks 21A extending in the first direction V and disposed to be aligned in the second direction H perpendicular to the first direction V through the insulating layer 53. Each block 21A is provided with, for example, multiple sets of the reset transistor RST, the amplification transistor AMP, and the selection transistor SEL. One readout circuit 22 shared by four sensor pixels 12 includes, for example, the reset transistor RST, the amplification transistor AMP, and the selection transistor SEL within a region opposed to the four sensor pixels 12. The one readout circuit 22 shared by the four sensor pixels 12 includes, for example, the amplification transistor AMP in a block 21A to the left of the insulating layer 53, the reset transistor RST and the selection transistor SEL in a block 21A to the right of the insulating layer 53.

FIGS. 19, 20, 21, and 22 illustrate an example of the wiring layout in a horizontal plane of the image sensor 1. FIGS. 19 to 22 illustrate a case where one readout circuit 22 shared by four sensor pixels 12 is provided within a region opposed to the four sensor pixels 12. Respective wires described in FIGS. 19 to 22 are provided, for example, in different layers from one another in the wiring layer 56.

For example, as illustrated in FIG. 19, four through-wires 54 adjacent to one another are electrically coupled to the coupling wires 55. For example, as illustrated in FIG. 19, the four through-wires 54 adjacent to one another are further electrically coupled to the gate of the amplification transistor AMP included in a block 21A to the left of the insulating layer 53 and the gate of the reset transistor RST included in a block 21A to the right of the insulating layer 53 through the coupling wires 55 and the coupling parts 59.

For example, as illustrated in FIG. 20, the power wire VDD is disposed to be opposed to the readout circuits 22 disposed to be aligned in the second direction H. For example, as illustrated in FIG. 20, the power wire VDD is electrically coupled to the drain of the amplification transistor AMP and the drain of the reset transistor RST of each of the readout circuits 22 disposed to be aligned in the second direction H. For example, as illustrated in FIG. 20, two pixel drive wires 23 are disposed in positions opposed to the readout circuits 22 disposed to be aligned in the second direction H. For example, as illustrated in FIG. 20, one (a second control wire) of the pixel drive wires 23 is a wire RSTG electrically coupled to the gate of the reset transistor RST of each of the readout circuits 22 disposed to be aligned in the second direction H. For example, as illustrated in FIG. 20, the other (a third control wire) of the pixel drive wires 23 is a wire SELG electrically coupled to the gate of the selection transistor SEL of each of the readout circuits 22 disposed to be aligned in the second direction H. For example, as illustrated in FIG. 20, in each readout circuit 22, the source of the amplification transistor AMP and the drain of the selection transistor SEL are electrically coupled to each other through a wire 25.

For example, as illustrated in FIG. 21, two power wires VSS are disposed in positions opposed to the readout circuits 22 disposed to be aligned in the second direction H. For example, as illustrated in FIG. 21, each of the power wires VSS is electrically coupled to the multiple through-wires 47 at positions opposed to the sensor pixels 12 disposed to be aligned in the second direction H. For example, as illustrated in FIG. 21, four pixel drive wires 23 are disposed in positions opposed to the readout circuits 22 disposed to be aligned in the second direction H. For example, as illustrated in FIG. 21, each of the four pixel drive wires 23 is a wire TRG electrically coupled to a through-wire 48 of one of four sensor pixels 12 corresponding to the respective readout circuits 22 disposed to be aligned in the second direction H. That is, the four pixel drive wires 23 (first control wires) are electrically coupled to the gate (the transfer gate TG) of the transfer transistor TR of each of the sensor pixels 12 disposed to be aligned in the second direction H. In FIG. 21, to distinguish the respective wires TRG, an identifier (1, 2, 3, or 4) is added to the end of each wire TRG.

For example, as illustrated in FIG. 22, the vertical signal wires 24 are disposed at positions opposed to the readout circuits 22 disposed to be aligned in the first direction V. For example, as illustrated in FIG. 22, the vertical signal wires 24 (output lines) are electrically coupled to the output terminal (the source of the amplification transistor AMP) of each of the readout circuits 22 disposed to be aligned in the first direction V.

### 1-4. Method of Manufacturing Image Sensor

Subsequently, a method of manufacturing the image sensor 1 is described. FIGS. 23A to 23G illustrate an example of a process of manufacturing the image sensor 1.

First, the p-well 42, the isolation part 43, and the p-well layer 44 are formed in the semiconductor substrate 11. Next, the photodiode PD, the transfer transistor TR, and the floating diffusion FD are formed in the semiconductor substrate 11 (FIG. 23A). Thus, the sensor pixel 12 is formed in the semiconductor substrate 11. At this time, it is preferable not to use, as an electrode material used in the sensor pixel 12, a low heat-resistance material such as CoSi₂ or NiSi treated by a salicide process. Instead, it is preferable to use a high heat-resistance material as an electrode material used in the sensor pixel 12. Examples of the high heat-resistance material include polysilicon. After that, the insulating layer 46 is formed on the semiconductor substrate 11 (FIG. 23A). The first substrate 10 is formed in this way.

Next, the semiconductor substrate 21 is bonded onto the first substrate 10 (an insulating layer 46B) (FIG. 23B). After that, the semiconductor substrate 21 is thinned down as necessary. At this time, the thickness of the semiconductor substrate 21 is caused to be a film thickness necessary for formation of the readout circuit 22. The thickness of the semiconductor substrate 21 is generally about a few hundreds nm. However, depending on a concept of the readout circuit 22, an FD (fully depletion) type is possible; therefore, in that case, a range of a few nm to a few um may be adopted as the thickness of the semiconductor substrate 21.

Then, in the same layer as the semiconductor substrate 21, the insulating layer 53 is formed (FIG. 23C). For example, the insulating layer 53 is formed in a portion opposed to the floating diffusion FD. For example, a slit (an opening 21H) going through the semiconductor substrate 21 is formed in the semiconductor substrate 21 to divide the semiconductor substrate 21 into the multiple blocks 21A. After that, the insulating layer 53 is formed to fill the slit. After that, in each of the blocks 21A of the semiconductor substrate 21, the readout circuit 22 including the amplification transistor AMP, etc. is formed (FIG. 23C). At this time, in a case where a high heat-resistance metal material is used as an electrode material of the sensor pixel 12, a gate insulating film of the readout circuit 22 is able to be formed by thermal oxidation.

Next, the insulating layer 52 is formed on the semiconductor substrate 21. In this way, the interlayer insulating film 51 including the insulating layers 46, 52, and 53 is formed. Then, through-holes 51A and 51B are formed in the interlayer insulating film 51 (FIG. 23D). Specifically, the through-hole 51B going through the insulating layer 52 is formed in, within the insulating layer 52, a portion opposed to the readout circuit 22. Furthermore, the through-hole 51A going through the interlayer insulating film 51 is formed in, within the interlayer insulating film 51, a portion opposed to the floating diffusion FD (i.e., a portion opposed to the insulating layer 53).

Then, by filling the through-holes 51A and 51B with a conductive material, the through-wire 54 is formed in the through-hole 51A, and the coupling part 59 is formed in the through-hole 51B (FIG. 23E). Furthermore, the coupling wire 55 electrically coupling the through-wire 54 and the coupling part 59 to each other is formed on the insulating layer 52 (FIG. 23E). After that, the wiring layer 56 is formed on the insulating layer 52 (FIG. 23F). The second substrate 20 is formed in this way.

Next, with the surface of the semiconductor substrate 21 directed toward the side of the surface of the semiconductor substrate 31, the second substrate 20 is bonded to the third substrate 30 with the logic circuit 32 and the wiring layer 62 formed therein (FIG. 32G). At this time, by joining the pad electrodes 58 of the second substrate 20 and the pad electrodes 64 of the third substrate 30, the second substrate 20 and the third substrate 30 are electrically coupled to each other. The image sensor 1 is manufactured in this way.

### 1-5. Action and Effects

In the wiring structure 100 of the present embodiment and the image sensor 1 to which the wiring structure 100 is applied, the conducting films 134 embedded in the surface 133S1 of the insulating layer 133 for forming air gaps G, for example, between multiple wires extending in the Y-axis direction have different film thicknesses in the air-gaps-forming region 100X and the other regions. Specifically, the conducting film 134X formed in the air-gaps-forming region 100X is formed to be thinner than the conducting films 134Y formed in the other regions. Thus, for example, there is secured the distance between multiple wires (for example, the wires 123X2 to 123X5), which extend in the Y-axis direction and are formed with air gaps G on their one or both sides between adjacent wires, and the conducting film 134X formed above those wires. This is described below.

In recent years, in semiconductor devices, spaces between wires connecting between and within elements have become narrower with the miniaturization of semiconductor integrated circuit elements, and the capacitance (parasitic capacitance) between wires tends to increase. An increase in the capacitance between wires causes a problem that a wiring signal is delayed, which results in the reduction of the operating speed of a device. Therefore, in general semiconductor devices, the parasitic capacitance between wires is sought to be reduced by using a low-k material to electrically insulate between wires in the stacking direction and providing air gaps between parallel wires.

In such semiconductor devices, after the formation of air gaps, an insulating layer including a low-k material is formed above the air gaps: however, on its surface, there is a depression due to the air gaps, thus a CMP process is performed in the subsequent process to planarize the surface. In a case where a conducting film is embedded in the insulating layer formed in this way, that conducting film has the same thickness in both an air-gaps region and a non-air-gaps region. Therefore, in such semiconductor devices, only the capacitance in a lateral direction of wires is reduced.

On the other hand, in the present embodiment, the conducting films 134 having different film thicknesses in the air-gaps-forming region 100X and the other regions are provided on the surface 133S1 of the insulating layer 133 for forming air gaps G, for example, between multiple wires extending in the Y-axis direction. This difference in film thickness of the conducting films 134 in the air-gaps-forming region 100X and the other regions is self-alignedly made as follows. For example, the surface 133S1 of the insulating layer 133 embedded with the conducting films 134 is formed with a step height (a depression) in the air-gaps-forming region 100X by the insulating layer 133 getting into the openings 122H3 in which air gaps G are formed. When the openings 133H1 and 133H2 to be embedded with the conducting films 134 are formed, first, a film having a different etching rate from the insulating layer 133 (for example, the SiO film 135) is formed on the insulating layer 133, and its surface is planarized. Then, the SiO film 135 formed in the air-gaps-forming region 100X becomes thicker than the SiO film 135 formed in the other regions by an amount equivalent of the step height of the insulating layer 133. After that, the openings 133H1 and 133H2 are formed using an etching condition for causing the etching rate of the insulating layer 133 to be faster than that of the SiO film 135, thereby the opening 134H1 formed in the air-gaps-forming region 100X becomes shallower than the openings 134H2 formed in the other regions. That is, the conducting film 134X formed in the air-gaps-forming region 100X is formed to be thinner than the conducting films 134Y formed in the other regions. Thus, for example, it is possible to secure the distance between multiple wires (for example, the wires 123X2 to 123X5), which extend in the Y-axis direction and are formed with air gaps G on their one or both sides between adjacent wires, and the conducting film 134X formed above those wires.

Consequently, the wiring structure 100 of the present embodiment makes it possible to reduce the wiring capacitance in the stacking direction in addition to the lateral direction. Therefore, it becomes possible to provide the image sensor 1 having an excellent device property.

Modification examples 1 to 10 are described below. It is noted that in the following description, the same component as the above-described embodiment is assigned the same reference numeral, and its description is omitted accordingly.

### 2. Modification Examples

### 2-1. Modification Example 1

FIG. 24 illustrates an example of a vertical cross-sectional configuration of an image sensor (the image sensor 1) according to a modification example (modification example 1) of the above-described embodiment. In the present modification example, the transfer transistor TR includes a planar transfer gate TG. Thus, the transfer gate TG does not go through the p-well 42, and is formed only on the surface of the semiconductor substrate 11. Even in a case where a planar transfer gate TG is used in the transfer transistor TR, the image sensor 1 has similar effects to the above-described embodiment.

### 2-2. Modification Example 2

FIG. 25 illustrates an example of a vertical cross-sectional configuration of an image sensor (the image sensor 1) according to a modification example (modification example 2) of the above-described embodiment. In the present modification example, electrical coupling of the second substrate 20 and the third substrate 30 is made in a region opposed to a peripheral 14 of the first substrate 10. The peripheral region 14 corresponds to a frame region of the first substrate 10, and is provided in the periphery of the pixel region 13. In the present modification example, the second substrate 20 includes the multiple pad electrodes 58 in a region opposed to the peripheral region 14, and the third substrate 30 includes the multiple pad electrodes 64 in a region opposed to the peripheral region 14. The second substrate 20 and the third substrate 30 are electrically coupled to each other by joining of the pad electrodes 58 and 64 provided in the regions opposed to the peripheral region 14.

In this way, in the present modification example, the second substrate 20 and the third substrate 30 are electrically coupled to each other by joining of the pad electrodes 58 and 64 provided in the regions opposed to the peripheral region 14. Thus, as compared with a case of joining of the pad electrodes 58 and 64 in regions opposed to the pixel region 13, it is possible to reduce the possibility of impeding the miniaturization of the area per pixel. Therefore, it is possible to provide the image sensor 1 of a three-layer structure that achieves the effects of the above-described embodiment and does not impede the miniaturization of the area per pixel with an equal chip size as before.

### 2-3. Modification Example 3

FIG. 26 illustrates an example of a vertical cross-sectional configuration of an image sensor (the image sensor 1) according to a modification example (modification example 3) of the above-described embodiment. FIG. 27 illustrates another example of the vertical cross-sectional configuration of the image sensor (the image sensor 1) according to the modification example (modification example 3) of the above-described embodiment. The upper diagrams of FIGS. 26 and 27 are modification examples of the cross-sectional configuration of the cross section Sec1 in FIG. 1, and the lower diagram of FIG. 26 is a modification example of the cross-sectional configuration of the cross section Sec2 in FIG. 1. It is noted that in the cross sections in the upper parts of the cross-sectional views in FIGS. 26 and 27, a diagram illustrating a modification example of the surface configuration of the semiconductor substrate 11 in FIG. 1 is overlaid on the diagram illustrating a modification example of the cross-sectional configuration of the cross section Sec1 in FIG. 1, and the insulating layer 46 is omitted. Furthermore, in the lower parts of the cross-sectional views in FIGS. 26 and 27, a diagram illustrating a modification example of the surface configuration of the semiconductor substrate 21 is overlaid on a diagram illustrating a modification example of the cross-sectional configuration of the cross section Sec2 in FIG. 1.

As illustrated in FIGS. 26 and 27, the multiple through-wires 54, the multiple through-wires 48, and the multiple through-wires 47 (multiple dots disposed in a matrix in the drawings) are disposed into strips in the first direction V (the right-left direction in FIGS. 26 and 27) within the plane of the first substrate 10. It is noted that FIGS. 26 and 27 illustrate a case where the multiple through-wires 54, the multiple through-wires 48, and the multiple through-wires 47 are disposed in two columns in the first direction V. In four sensor pixels 12 sharing the readout circuit 22, four floating diffusions FD are disposed, for example, close to one another through the isolation part 43. In the four sensor pixels 12 sharing the readout circuit 22, the four transfer gates TG (TG1, TG2, TG3, and TG4) are disposed to surround the four floating diffusions FD, and, for example, an annular shape is formed by the four transfer gates TG.

The insulating layer 53 includes multiple blocks extending in the first direction V. The semiconductor substrate 21 includes the multiple insular blocks 21A extending in the first direction V and disposed to be aligned in the second direction H perpendicular to the first direction V through the insulating layer 53. Each block 21A is provided with, for example, the reset transistor RST, the amplification transistor AMP, and the selection transistor SEL. For example, one readout circuit 22 shared by four sensor pixels 12 is not disposed face-to-face with the four sensor pixels 12, and is disposed to be displaced in the second direction H.

In FIG. 26, one readout circuit 22 shared by four sensor pixels 12 includes the reset transistor RST, the amplification transistor AMP, and the selection transistor SEL within a region displaced in the second direction H from the region opposed to the four sensor pixels 12 in the second substrate 20. The one readout circuit 22 shared by the four sensor pixels 12 includes, for example, the amplification transistor AMP, the reset transistor RST, and the selection transistor SEL in one block 21A.

In FIG. 27, one readout circuit 22 shared by four sensor pixels 12 includes the reset transistor RST, the amplification transistor AMP, the selection transistor SEL, and FD transfer transistor FDG within a region displaced in the second direction H from the region opposed to the four sensor pixels 12 in the second substrate 20. The one readout circuit 22 shared by the four sensor pixels 12 includes, for example, the amplification transistor AMP, the reset transistor RST, the selection transistor SEL, and FD transfer transistor FDG in one block 21A.

In the present modification examples, for example, one readout circuit 22 shared by four sensor pixels 12 is not disposed face-to-face with the four sensor pixels 12, and is disposed to be displaced in the second direction H from a position at which it comes face-to-face with the four sensor pixels 12. In such a case, it is possible to make the wire 25 shorter, or it is possible to omit the wire 25 and cause the source of the amplification transistor AMP and the drain of the selection transistor SEL to be included in a shared impurity region. As a result, it is possible to reduce the size of the readout circuit 22 or increase the size of the other part in the readout circuit 22.

### 2-4. Modification Example 4

FIG. 28 illustrates an example of a horizontal cross-sectional configuration of an image sensor (the image sensor 1) according to a modification example (modification example 4) of the above-described embodiment. FIG. 28 illustrates a modification example of the cross-sectional configuration in FIG. 14.

In the present modification example, the semiconductor substrate 21 includes the multiple insular blocks 21A disposed to be aligned in the first direction V and the second direction H through the insulating layer 53. Each block 21A is provided with, for example, one set of the reset transistor RST, the amplification transistor AMP, and the selection transistor SEL. In such a case, it is possible to suppress the crosstalk between the readout circuits 22 adjacent to each other by the insulating layer 53, and is possible to suppress the decrease of the resolution on a reproduced image and the degradation of the image quality caused by mixing of colors.

### 2-5. Modification Example 5

FIG. 29 illustrates an example of a horizontal cross-sectional configuration of an image sensor (the image sensor 1) according to a modification example (modification example 5) of the above-described embodiment. FIG. 29 illustrates a modification example of the cross-sectional configuration in FIG. 28.

In the present modification example, for example, one readout circuit 22 shared by four sensor pixels 12 is not disposed face-to-face with the four sensor pixels 12, and is disposed to be displaced in the first direction V. Furthermore, in the present modification example, as with modification example 4, the semiconductor substrate 21 includes the multiple insular blocks 21A disposed to be aligned in the first direction V and the second direction H through the insulating layer 53. Each block 21A is provided with, for example, one set of the reset transistor RST, the amplification transistor AMP, and the selection transistor SEL. Moreover, in the present modification example, the multiple through-wires 47 and multiple through-wires 54 are also arranged in the second direction H. Specifically, the multiple through-wires 47 are disposed between four through-wires 54 sharing one readout circuit 22 and four through-wires 54 sharing another readout circuit 22 adjacent to that readout circuit 22 in the second direction H. In such a case, it is possible to suppress the crosstalk between the readout circuits 22 adjacent to each other by the insulating layer 53 and the through-wires 47, and is possible to suppress the decrease of the resolution on a reproduced image and the degradation of the image quality caused by mixing of colors.

### 2-6. Modification Example 6

FIG. 30 illustrates an example of a horizontal cross-sectional configuration of an image sensor (the image sensor 1) according to a modification example (modification example 6) of the above-described embodiment. FIG. 30 illustrates a modification example of the cross-sectional configuration in FIG. 13.

In the present modification example, the first substrate 10 includes the photodiode PD and the transfer transistor TR for each sensor pixel 12, and the floating diffusion FD is shared by every four sensor pixels 12. Therefore, in the present modification example, one through-wire 54 is provided for every four sensor pixels 12.

In the multiple sensor pixels 12 disposed in a matrix, four sensor pixels 12 corresponding to a region obtained by displacing the unit region corresponding to four sensor pixels 12 sharing one floating diffusion FD by an amount equivalent of one sensor pixel 12 in the first direction V is conveniently referred to as four sensor pixels 12A. At this time, in the present modification example, in the first substrate 10, the through-wire 47 is shared by every four sensor pixels 12A. Therefore, in the present modification example, one through-wire 47 is provided for every four sensor pixels 12A.

In the present modification example, the first substrate 10 includes the isolation part 43 that isolates the photodiode PD and the transfer transistor TR with respect to each sensor pixel 12. As viewed from the normal direction, the isolation part 43 does not completely surround the sensor pixel 12, and has gaps (unformed regions) near the floating diffusion FD (the through-wire 54) and near the through-wire 47. Then, those gaps enable sharing of one through-wire 54 by four sensor pixels 12 and sharing of one through-wire 47 by four sensor pixels 12A. In the present modification example, the second substrate 20 includes the readout circuit 22 for every four sensor pixels 12 sharing the floating diffusion FD.

FIG. 31 illustrates another example of the horizontal cross-sectional configuration of the image sensor 1 according to the present modification example. FIG. 31 illustrates a modification example of the cross-sectional configuration in FIG. 28. In the present modification example, the first substrate 10 includes the photodiode PD and the transfer transistor TR for each sensor pixel 12, and the floating diffusion FD is shared by every four sensor pixels 12. Furthermore, the first substrate 10 includes the isolation part 43 that isolates the photodiode PD and the transfer transistor TR with respect to each sensor pixel 12.

FIG. 32 illustrates still another example of the horizontal cross-sectional configuration of the image sensor 1 according to the present modification example. FIG. 32 illustrates a modification example of the cross-sectional configuration in FIG. 29. In the present modification example, the first substrate 10 includes the photodiode PD and the transfer transistor TR for each sensor pixel 12, and the floating diffusion FD is shared by every four sensor pixels 12. Furthermore, the first substrate 10 includes the isolation part 43 that isolates the photodiode PD and the transfer transistor TR with respect to each sensor pixel 12.

### 2-7. Modification Example 7

FIG. 33 illustrates an example of a circuit configuration of an image sensor (the image sensor 1) according to a modification example (modification example 7) of the above-described embodiment and modification examples 1 to 6. The image sensor 1 according to the present modification example is a CMOS sensor equipped with column parallel ADCs.

As illustrated in FIG. 33, the image sensor 1 according to the present modification example includes the vertical drive circuit 33, the column signal processing circuit 34, a reference voltage supply part 38, the horizontal drive circuit 35, a horizontal output line 37, and the system control circuit 36 in addition to the pixel region 13 in which the multiple sensor pixels 12 each including a photoelectric conversion element are two-dimensionally disposed in a matrix.

In this system configuration, the system control circuit 36 generates a clock signal, a control signal, etc. to be the basis of the operation of the vertical drive circuit 33, the column signal processing circuit 34, the reference voltage supply part 38, the horizontal drive circuit 35, etc. on the basis of a master clock MCK, and gives the generated signal to the vertical drive circuit 33, the column signal processing circuit 34, the reference voltage supply part 38, the horizontal drive circuit 35, etc.

Furthermore, along with the sensor pixels 12 in the pixel region 13, the vertical drive circuit 33 is formed in the first substrate 10, and is also formed in the second substrate 20 formed with the readout circuits 22. The column signal processing circuit 34, the reference voltage supply part 38, the horizontal drive circuit 35, the horizontal output line 37, and the system control circuit 36 are formed in the third substrate 30.

Although are not illustrated in the drawings here, for example, a configuration including the photodiode PD and the transfer transistor TR that transfers an electric charge obtained by a photoelectric conversion by the photodiode PD into the floating diffusion FD is able to be used as the sensor pixel 12. Furthermore, although are not illustrated in the drawings here, for example, a three-transistor configuration including the reset transistor RST that controls a potential of the floating diffusion FD, the amplification transistor AMP that outputs a signal in accordance with the potential of the floating diffusion FD, and the selection transistor SEL for selection of a pixel is able to be used as the readout circuit 22.

In the pixel region 13, the sensor pixels 12 are two-dimensionally disposed, and, with respect to this m-row n-column pixel array, the pixel drive wire 23 is provided for each row, and the vertical signal wire 24 is provided for each column. Respective one ends of the multiple pixel drive wires 23 are coupled to output terminals corresponding to the rows of the vertical drive circuit 33. The vertical drive circuit 33 includes a shift register, etc., and performs control of the row address of the pixel region 13 and row scanning through the multiple pixel drive wires 23.

The column signal processing circuit 34 includes, for example, ADCs (analog-digital converter circuits) 34-1 to 34-m provided, one for each column of pixels in the pixel region 13, i.e., one for each vertical signal wire 24, and converts an analog signal output from each sensor pixel 12 in the pixel region 13 column by column into a digital signal and outputs the digital signal.

The reference voltage supply part 38 includes, for example, a DAC (a digital-analog converter circuit) 38A as a means of generating a reference voltage Vref whose level varies in slope as time passes, i.e., of a so-called ramp waveform. It is noted that the means of generating a reference voltage Vref of a ramp waveform is not limited to the DAC 38A.

Under the control based on a control signal CS1 given from the system control circuit 36, the DAC 38A generates a reference voltage Vref of a ramp waveform on the basis of a clock CK given from the system control circuit 36 and supplies the reference voltage Vref to the ADCs 34-1 to 34-m of the column signal processing circuit 34.

It is noted that each of the ADCs 34-1 to 34-m is configured to be able to selectively perform an AD conversion operation corresponding to the operation mode, a normal frame rate mode by a progressive scan method of reading out information of all the sensor pixels 12 or a high-speed frame rate mode in which the frame rate is increased to N times, for example, twice the frame rate in the normal frame rate mode by setting the exposure time of the sensor pixels 12 to 1/N. This switching of the operation mode is performed by control based on control signals CS2 and CS3 given from the system control circuit 36. Furthermore, information of an instruction to switch the operation mode between the normal frame rate mode and the high-speed frame rate mode is given to the system control circuit 36 from an external system controller (not illustrated).

The ADCs 34-1 to 34-m all have the same configuration, and the ADC 34-mis described here as an example. The ADC 34-m includes a comparator 34A, an up/down counter (denoted by U/DCNT in the drawing) 34B as an example of a counting means, a transfer switch 34C, and a memory device 34D.

The comparator 34A compares a signal voltage Vx of the vertical signal wire 24 in accordance with respective signals output from the sensor pixels 12 in the nth column of the pixel region 13 and the reference voltage Vref of the ramp waveform supplied from the reference voltage supply part 38: for example, when the reference voltage Vref has become higher than the signal voltage Vx, an output Vco becomes “H” level, and when the reference voltage Vref is equal to or lower than the signal voltage Vx, an output Vco is “L” level.

The up/down counter 34B is an asynchronous counter, and, under the control based on a control signal CS2 given from the system control circuit 36, is given a clock CK from the system control circuit 36 at the same time when a clock CK is given to the DAC 18A, and counts down or up in synchronization with the clock CK, thereby measuring a period of comparison from the start to the end of a comparison operation by the comparator 34A.

Specifically, in the normal frame rate mode, in an operation of reading out a signal from one sensor pixel 12, comparison time in the first readout is measured by counting down in the first readout operation, and comparison time in the second readout is measured by counting up in the second readout operation.

Meanwhile, in the high-speed frame rate mode, a counting result with respect to a sensor pixel 12 in one row is held as it is, and then, with respect to a sensor pixel 12 in the next row, comparison time in the first readout is measured by counting down from the previous counting result in the first readout operation, and comparison time in the second readout is measured by counting up in the second readout operation.

Under the control based on a control signal CS3 given from the system control circuit 36, in the normal frame rate mode, upon completion of a counting operation by the up/down counter 34B with respect to a sensor pixel 12 in one row, the transfer switch 34C falls into on (closed) state, and transfers a counting result from the up/down counter 34B into the memory device 34D.

Meanwhile, for example, at a high-speed frame rate of N=2, upon completion of a counting operation by the up/down counter 34B with respect to a sensor pixel 12 in one row, the transfer switch 34C is kept in off (open) state, and then, upon completion of a counting operation by the up/down counter 34B with respect to a sensor pixel 12 in the next row, the transfer switch 34C falls into on state, and transfers counting results for the two vertical pixels from the up/down counter 34B into the memory device 34D.

In this way, by the respective operation of the comparators 34A and the up/down counters 34B in the ADCs 34-1 to 34-m, an analog signal supplied from each sensor pixel 12 in the pixel region 13 column by column through the vertical signal wire 24 is converted into an N-bit digital signal, and the digital signal is stored in the memory device 34D.

The horizontal drive circuit 35 includes a shift register, etc., and performs control of column addresses of the ADCs 34-1 to 34-m in the column signal processing circuit 34 and column scanning. Under the control of this horizontal drive circuit 35, respective N-bit digital signals AD-converted by the ADCs 34-1 to 34-m are sequentially read out into the horizontal output line 37, and are output as imaging data through the horizontal output line 37.

It is noted that since it is not directly associated with the present disclosure, a circuit or something that performs a variety of signal processing on the imaging data output through the horizontal output line 37 is not particularly illustrated in the drawings, and yet is able to be provided besides the above-described components.

In the image sensor 1 equipped with the column parallel ADCs according to the present modification example having the above-described configuration, it is possible to selectively transfer a counting result from the up/down counter 34B into the memory device 34D through the transfer switch 34C: therefore, it is possible to independently control an operation of reading out the counting result from the up/down counter 34B into the horizontal output line 37.

### 2-8. Modification Example 8

FIG. 34 illustrates an example where the image sensor in FIG. 33 includes three substrates (the first substrate 10, the second substrate 20, and the third substrate 30) stacked on top of another. In the present modification example, in the first substrate 10, the pixel region 13 including the multiple sensor pixels 12 is formed in the middle part, and the vertical drive circuit 33 is formed around the pixel region 13. Furthermore, in the second substrate 20, a readout circuit region 15 including the multiple readout circuits 22 is formed in the middle part, and the vertical drive circuit 33 is formed around the readout circuit region 15. In the third substrate 30, the column signal processing circuit 34, the horizontal drive circuit 35, the system control circuit 36, the horizontal output line 37, and the reference voltage supply part 38 are formed. Thus, as with the above-described embodiment and its modification examples, it does not happen that due to a structure in which substrates are electrically coupled to each other, the chip size is increased, or the miniaturization of the area per pixel is impeded. Consequently, it is possible to provide the image sensor 1 of a three-layer structure that does not impede the miniaturization of the area per pixel with an equal chip size as before. It is noted that the vertical drive circuit 33 may be formed only in the first substrate 10, or may be formed only in the second substrate 20.

### 2-9. Modification Example 9

FIG. 35 illustrates an example of a cross-sectional configuration of an image sensor (the image sensor 1) according to a modification example (modification example 9) of the above-described embodiment and its modification examples 1 to 8. In the above-described embodiment and modification examples 1 to 8, etc., the image sensor 1 includes three substrates (the first substrate 10, the second substrate 20, and the third substrate 30) stacked on top of another. However, like the image sensors 5 and 6 in the above-described fifth embodiment, it may includes two substrates (the first substrate 10 and the second substrate 20) stacked on top of each other. At this time, for example, as illustrated in FIG. 35, the logic circuits 32 may be separately formed in the first substrate 10 and the second substrate 20. Here, of the logic circuits 32, a circuit 32A provided in the first substrate 10 side is provided with a transistor having a gate structure in which a high-dielectric constant film including a material that is able to withstand a high-temperature process (for example, high-k) and a gate electrode are stacked on top of each other. Meanwhile, a circuit 32B provided in the second substrate 20 side is formed with a low-resistance region 26 including silicide such as CoSiz or NiSi formed using a self-aligned silicide process on a surface of an impurity diffused region in contact with a source electrode and a drain electrode. The low-resistance region including silicide is formed of a compound of the material of the semiconductor substrate and metal. Thus, a high-temperature process such as thermal oxidation is able to be used when the sensor pixels 12 are formed. Furthermore, in a case where, of the logic circuits 32, in the circuit 32B provided in the second substrate 20, the low-resistance region 26 including silicide is provided on the surface of the impurity diffused region in contact with the source electrode and the drain electrode, it is possible to reduce the contact resistance. As a result, it is possible to make the operation speed of the logic circuits 32 faster.

### 2-10. Modification Example 10

FIG. 36 illustrates a modification example of the cross-sectional configuration of the image sensor 1 according to a modification example (modification example 10) of the above-described embodiment and its modification examples 1 to 8. In the logic circuit 32 of the third substrate 30 according to the above-described embodiment and its modification examples 1 to 8, a low-resistance region 39 including silicide such as CoSi₂or NiSi formed using a self-aligned silicide process may be formed on the surface of the impurity diffused region in contact with the source electrode and the drain electrode. Thus, a high-temperature process such as thermal oxidation is able to be used when the sensor pixels 12 are formed. Furthermore, in a case where in the logic circuit 32, the low-resistance region 39 including silicide is provided on the surface of the impurity diffused region in contact with the source electrode and the drain electrode, it is possible to reduce the contact resistance. As a result, it is possible to make the operation speed of the logic circuit 32 faster.

It is noted that in the above-described embodiment and its modification examples 1 to 10, the conductivity types may be reversed. For example, in the description of the above-described embodiment and its modification examples 1 to 10, the p-type may be replaced with the n-type, and the n-type may be replaced with the p-type. Even in a case where it has been done, it is possible to achieve similar effects to the first and fifth embodiments and their modification examples 1 to 10.

### 3. Application Example

FIG. 37 illustrates an example of a schematic configuration of an imaging system 7 including the image sensor (the image sensor 1) according to the above-described embodiment and its modification examples 1 to 10.

The imaging system 7 is an electronic apparatus, for example, an imaging device such as a digital still camera or a video camera, a mobile terminal device such as a smartphone or a tablet terminal device, etc. The imaging system 7 includes, for example, an optical system 241, a shutter device 242, the image sensor 1, a DSP circuit 243, a frame memory 244, a display unit 245, a storage unit 246, an operation unit 247, and a power supply unit 248. In the imaging system 7, the shutter device 242, the image sensor 1, the DSP circuit 243, the frame memory 244, the display unit 245, the storage unit 246, the operation unit 247, and the power supply unit 248 are coupled to one another through a bus line 249.

The image sensor 1 outputs image data in accordance with incident light. The optical system 241 includes one or more lenses, and guides light (incident light) from a subject to the image sensor 1, and causes an image to be formed on a light receiving surface of the image sensor 1. The shutter device 242 is disposed between the optical system 241 and the image sensor 1, and controls a period in which the image sensor 1 is irradiated with light and a period in which the image sensor 1 is shielded from light in accordance with the control of the operation unit 247. The DSP circuit 243 is a signal processing circuit that processes a signal (image data) output from the image sensor 1. The frame memory 244 temporarily holds the image data processed by the DSP circuit 243 by frame. The display unit 245 includes, for example, a panel display device such as a liquid crystal panel or an organic EL (electro luminescent) panel, and displays thereon a moving image or a static image taken by the image sensor 1. The storage unit 246 stores image data of the moving image or the static image taken by the image sensor 1 in a storage medium such as a semiconductor memory or a hard disk. The operation unit 247 issues an operation instruction about various functions that the imaging system 7 has in accordance with a user's operation. The power supply unit 248 appropriately supplies the image sensor 1, the DSP circuit 243, the frame memory 244, the display unit 245, the storage unit 246, and the operation unit 247 with a variety of electric power that is the power for those to be supplied to operate.

Subsequently, an imaging procedure of the imaging system 7 is described.

FIG. 38 illustrates an example of a flowchart of the imaging operation of the imaging system 7. A user issues an instruction to start the imaging by operating the operation unit 247 (step S101). Then, the operation unit 247 transmits the imaging instruction to the image sensor 1 (step S102). When having received the imaging instruction, the image sensor 1 (specifically, the system control circuit 36) performs imaging by a predetermined imaging method (step S103).

The image sensor 1 outputs light (image data) formed on the light receiving surface through the optical system 241 and the shutter device 242 to the DSP circuit 243. The image data here is data of pixel signals of all pixels generated on the basis of electric charges temporarily held in the floating diffusions FD. The DSP circuit 243 performs predetermined signal processing (for example, a noise reduction process, etc.) on the basis of the image data input from the image sensor 1 (step S104). The DSP circuit 243 causes the frame memory 244 to hold the image data subjected to the predetermined signal processing, and the frame memory 244 causes the storage unit 246 to store therein the image data (step S105). The imaging of the imaging system 7 is performed in this way.

In the present application example, the image sensor 1 is applied to the imaging system 7. Thus, it becomes possible to make the image sensor 1 a miniaturized or high-definition image sensor, and therefore it becomes possible to provide the miniaturized or high-definition imaging system 7.

FIG. 39 is a diagram illustrating an outline of configuration examples of a non-stacked solid-state image sensor (a solid-state image sensor 23210) and a stacked solid-state image sensor (a solid-state image sensor 23020) to which the technique according to the present disclosure may be applied.

Part A of FIG. 39 illustrates a schematic configuration example of the non-stacked solid-state image sensor. The solid-state image sensor 23010 includes one die (semiconductor substrate) 23011 as illustrated in part A of FIG. 39. On this die 23011, a pixel region 23012 with pixels disposed in an array, a control circuit 23013 that performs various controls such as driving of the pixels, and a logic circuit 23014 for performing signal processing are mounted.

Parts B and C of FIG. 39 illustrate a schematic configuration example of the stacked solid-state image sensor. As illustrated in parts B and C of FIG. 39, in the solid-state image sensor 23020, two dies, a sensor die 23021 and a logic die 23024 are stacked on top of each other and electrically coupled to each other, and are configured as one semiconductor chip. The sensor die 23021 and the logic die 23024 correspond to a specific example of the “first substrate” and the “second substrate” of the present disclosure, respectively.

In part B of FIG. 39, the pixel region 23012 and the control circuit 23013 are mounted on the sensor die 23021, and the logic circuit 23014 including a signal processing circuit that performs signal processing is mounted on the logic die 23024. Furthermore, for example, the above-described readout circuit 22, etc. may be mounted on the sensor die 23021.

In part C of FIG. 39, the pixel region 23012 is mounted on the sensor die 23021, and the control circuit 23013 and the logic circuit 23014 are mounted on the logic die 23024.

FIG. 40 is a cross-sectional view illustrating a first configuration example of the stacked solid-state image sensor 23020.

The sensor die 23021 is formed with a PD (photodiode), an FD (floating diffusion), a Tr (MOS FET), a Tr to be made into the control circuit 23013, etc. that are included in each of the pixels to be made into the pixel region 23012. Furthermore, the sensor die 23021 is formed with a wiring layer 23101 including multiple layers, in the present example, three layers of wires 23110. It is noted that the control circuit 23013 (that the Tr is made into) is able to be included in not the sensor die 23021 but the logic die 23024.

The logic die 23024 is formed with the Tr to be included in the logic circuit 23014. Furthermore, the logic die 23024 is formed with a wiring layer 23161 including multiple layers, in the present example, three layers of wires 23170. Moreover, the logic die 23024 is formed with a contact hole 23171 with an insulating film 23172 formed on its inner wall surface, and a coupled conductor 23173 coupled to the wires 23170, etc. is embedded in the contact hole 23171.

The sensor die 23021 and the logic die 23024 are bonded to cause their respective wiring layers 23101 and 23161 to be opposed to each other, thus, the stacked solid-state image sensor 23020 with the sensor die 23021 and the logic die 23024 stacked on top of each other is configured. A film 23191 such as a protective film is formed on a bonded surface of the sensor die 23021 and the logic die 23024.

The sensor die 23021 is formed with a contact hole 23111 that goes through the sensor die 23021 from the side of a back surface of the sensor die 23021 (the side that light enters the PD) (the upper side) and reaches the wires 23170 of the uppermost layer of the logic die 23024. Furthermore, the sensor die 23021 is formed with a contact hole 23121 that is close to the contact hole 23111 and reaches the wires 23110 of the first layer from the side of the back surface of the sensor die 23021. An insulating film 23112 is formed on an inner wall surface of the contact hole 23111, and an insulating film 23122 is formed on an inner wall surface of the contact hole 23121. Then, coupled conductors 23113 and 23123 are embedded in the contact holes 23111 and 23121, respectively. The coupled conductors 23113 and 23123 are electrically coupled to each other on the side of the back surface of the sensor die 23021, thus the sensor die 23021 and the logic die 23024 are electrically coupled to each other through the wiring layer 23101, the contact hole 23121, the contact hole 23111, and the wiring layer 23161.

FIG. 41 is a cross-sectional view illustrating a second configuration example of the stacked solid-state image sensor 23020.

In the second configuration example of the solid-state image sensor 23020, ((the wires 23110 of) the wiring layer 23101 of) the sensor die 23021 and ((the wires 23170 of) the wiring layer 23161 of) the logic die 23024 are electrically coupled to each other by one contact hole 23211 formed on the sensor die 23021.

That is, in FIG. 41, the contact hole 23211 is formed to go through the sensor die 23021 from the side of the back surface of the sensor die 23021 and reach the wires 23170 of the uppermost layer of the logic die 23024 and also reach the wires 23110 of the uppermost layer of the sensor die 23021. An insulating film 23212 is formed on an inner wall surface of the contact hole 23211, and a coupled conductor 23213 is embedded in the contact hole 23211. In FIG. 40 described above, the sensor die 23021 and the logic die 23024 are electrically coupled to each other by the two contact holes 23111 and 23121; however, in FIG. 41, the sensor die 23021 and the logic die 23024 are electrically coupled to each other by the one contact hole 23211.

FIG. 42 is a cross-sectional view illustrating a third configuration example of the stacked solid-state image sensor 23020.

The solid-state image sensor 23020 of FIG. 42 differs from the case of FIG. 41, where the film 23191 such as a protective film is formed on the bonded surface of the sensor die 23021 and the logic die 23024, in that the film 23191 such as a protective film is not formed on the bonded surface of the sensor die 23021 and the logic die 23024.

The solid-state image sensor 23020 of FIG. 42 is configured by the sensor die 23021 and the logic die 23024 being overlaid to cause their respective wires 23110 and 23170 to come in direct contact with each other and directly joining the wires 23110 and 23170 by being heated while being subject to necessary weight bearing.

FIG. 43 is a cross-sectional view illustrating another configuration example of the stacked solid-state image sensor to which the technique according to the present disclosure may be applied.

In FIG. 43, a solid-state image sensor 23401 has a three-layer stacked structure in which three dies, a sensor die 23411, a logic die 23412, and a memory die 23413, are stacked on top of one another.

The memory die 23413 includes, for example, a memory circuit that performs storage of data temporarily necessary in signal processing performed by the logic die 23412.

In FIG. 43, under the sensor die 23411, the logic die 23412 and the memory die 23413 are stacked in that order; however, the logic die 23412 and the memory die 23413 are able to be stacked in reverse order: that is, they are able to be stacked under the sensor die 23411 in the order of the memory die 23413 and the logic die 23412.

It is noted that in FIG. 43, the sensor die 23411 is formed with a PD to be made into a photoelectric conversion part of pixels and a source/drain region of a pixel Tr.

A gate electrode is formed around the PD through a gate insulating film, and pixels Tr23421 and Tr23422 are formed by a source/drain region paired up with the gate electrode.

The pixel Tr23421 adjacent to the PD is a transfer Tr, and one of a pair of source/drain regions constituting that pixel Tr23421 is an FD.

Furthermore, the sensor die 23411 is formed with an interlayer insulating film, and a contact hole is formed on the interlayer insulating film. The pixel Tr23421 and a coupled conductor 23431 coupled to the pixel Tr23422 are formed in the contact hole.

Moreover, the sensor die 23411 is formed with a wiring layer 23433 including multiple layers of wires 23432 coupled to the coupled conductors 23431.

Furthermore, an aluminum pad 23434 serving as an electrode for external coupling is formed on the lowermost layer of the wiring layer 23433 of the sensor die 23411. That is, in the sensor die 23411, the aluminum pad 23434 is formed in a position closer to a bonded surface 23440 to the logic die 23412 than the wires 23432. The aluminum pad 23434 is used as one end of a wire related to an input/output of a signal from/to the outside.

Moreover, the sensor die 23411 is formed with a contact 23441 used for electrical coupling to the logic die 23412. The contact 23441 is coupled to a contact 23451 of the logic die 23412, and is also coupled to an aluminum pad 23442 of the sensor die 23411.

Then, the sensor die 23411 is formed with a pad hole 23443 that reaches the aluminum pad 23442 from the side of a back surface of the sensor die 23411 (the upper side).

The technique according to the present disclosure is applicable to the solid-state image sensor described above. For example, the wires 23110 and the wiring layer 23161 may be provided with, for example, the multiple pixel drive wires 23 and the multiple vertical signal wires 24 described above. In that case, by forming air gaps G like those illustrated in FIG. 1 between these multiple vertical signal wires 24, it becomes possible to reduce the capacitance between wires. Furthermore, by suppressing the increase of the capacitance between wires, it becomes possible to reduce the variation in the wiring capacitance.

### 4. Practical Application Examples Practical Application Example 1

The technique according to the present disclosure (the present technology) is applicable to various products. For example, the technique according to the present disclosure may be realized as a device mounted on any of types of moving bodies such as a motor vehicle, an electric vehicle, a hybrid electric vehicle, a motorcycle, a bicycle, a personal transporter, an airplane, a drone, a vessel, and a robot.

FIG. 44 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 44, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 44, an audio speaker 12061, a display section 12062, and an instrument panel 12063 are illustrated as the output device. The display section 12062 may, for example, include at least one of an on-board display and a head-up display.

FIG. 45 is a diagram depicting an example of the installation position of the imaging section 12031.

In FIG. 45, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 45 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As above, there is described an example of the moving body control system to which the technique according to the present disclosure may be applied. The technique according to the present disclosure may be applied to, of the above-described components, the imaging section 12031. Specifically, the image sensor 1 according to the above-described embodiment and its modification examples is applicable to the imaging section 12031. By applying the technique according to the present disclosure to the imaging section 12031, it becomes possible to obtain a high-definition taken image with less noise; therefore, it is possible to perform high-precision control using the taken image in the moving body control system.

### Practical Application Example 2

FIG. 46 is a view depicting an example of a schematic configuration of an endoscopic surgery system to which the technology according to an embodiment of the present disclosure (present technology) can be applied.

In FIG. 46, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 47 is a block diagram depicting an example of a functional configuration of the camera head 11102 and the CCU 11201 depicted in FIG. 46.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As above, there is described an example of the endoscopic surgery system to which the technique according to the present disclosure may be applied. The technique according to the present disclosure may be suitably applied to, of the above-described components, the imaging pickup unit 11402 provided in the camera head 11102 of the endoscope 11100. By applying the technique according to the present disclosure to the imaging pickup unit 11402, it becomes possible to make the imaging pickup unit 11402 a miniaturized or high-definition imaging pickup unit, and therefore it becomes possible to provide the miniaturized or high-definition endoscope 11100.

The present disclosure is described above with the embodiment and its modification examples 1 to 10, the application example, and the practical application examples: however, the present disclosure is not limited to the above-described embodiment, etc., and it is possible to make various modifications. For example, in the above-described embodiment, etc., there is provided an example where the multiple pixel drive wires 23 extend in the row direction, and the multiple vertical signal wires extend in the column direction: alternatively, both may extend in the same direction. Furthermore, that extending direction of the pixel drive wires 23 is able to be appropriately changed to the vertical direction or some other direction.

Moreover, in the above-described embodiment, etc., the present technology is described with the image sensor 1 having a three-dimensional structure as an example: however, the present technology is not limited to this. The present technology is applicable to every three-dimensional stacked, large-scale integrated (LSI) semiconductor device.

It is noted that the effects described in the present specification are merely an example. The effects of the present disclosure are not limited to those described in the present specification. The present disclosure may have effects other than those described in the present specification.

It is noted that the present disclosure may have the following configuration. According to the present technology having the following configuration, of conducting films provided above a wiring layer including multiple wires extending in one direction and formed and embedded in a first surface of a first insulating layer with air gaps formed between adjacent wires of the wiring layer, a first conducting film formed in a first region including the air gaps and the adjacent wires between which the air gaps have been formed is made thinner than a second conducting film formed in a second region not including air gaps and adjacent wires between which the air gaps have been formed. Thus, there is secured the distance between multiple wires extending in the one direction and a conducting film (the first conducting film) formed above the wires, which makes it possible to reduce the wiring capacitance in the stacking direction.

(1)

An image sensor including:
a wiring layer including multiple wires extending in one direction;
a first insulating layer with air gaps formed in at least some of regions between adjacent wires of the multiple wires;
a first conducting film formed and embedded in a first surface of the first insulating layer in a first region including the air gaps and the adjacent wires between which the air gaps have been formed; and
a second conducting film formed and embedded in the first surface of the first insulating layer in a second region not including the air gaps and the adjacent wires between which the air gaps have been formed, the second conducting film being thicker than the first conducting film.
   (2)

The image sensor according to (1), in which respective surfaces of the first conducting film and the second conducting film are exposed on the first surface of the first insulating layer.

(3)

The image sensor according to (1) or (2), in which the first conducting film and the second conducting film are independent from each other with the first insulating layer between the first conducting film and the second conducting film.

(4)

The image sensor according to any one of (1) to (3), in which the first conducting film and the second conducting film form a continuous conducting film, and the inside of the conducting film has different in-plane thicknesses.

(5)

The image sensor according to any one of (1) to (4), in which the first insulating layer is formed using a low-dielectric constant material having a relative dielectric constant k of 3.0 or lower.

(6)

The image sensor according to any one of (1) to (5), further including a barrier film stacked on the wiring layer, an end surface of the barrier film being located above any of the multiple wires.

(7)

The image sensor according to (6), further including a second insulating layer provided between the first insulating layer and the barrier film and extending over the end surface, upper and side surfaces of the multiple wires, and below the air gaps.

(8)

The image sensor according to any one of (1) to (7), further including: a first substrate including a first semiconductor substrate including a sensor pixel that performs photoelectric conversion and a first multi-layer wiring layer including the wiring layer, the first insulating layer, the first conducting film, and the second conducting film; and
a second substrate including a second semiconductor substrate including a logic circuit that processes a pixel signal based on an electric charge output from the sensor pixel and a second multi-layer wiring layer formed and embedded with one or more third conducting films in a second surface on the side opposite to the side of the second semiconductor substrate,
in which the first substrate and the second substrate are electrically coupled to each other by joining of the first conducting film and the second conducting film to the one or more third conducting films.
   (9)

The image sensor according to (8), in which the first substrate further includes a third semiconductor substrate provided with a readout circuit between the first semiconductor substrate and the first multi-layer wiring layer, the readout circuit outputting the pixel signal based on the electric charge output from the sensor pixel to the logic circuit.

(10)

The image sensor according to (8) or (9), in which the second substrate further includes a readout circuit that outputs the pixel signal based on the electric charge output from the sensor pixel to the logic circuit, and the readout circuit is provided in a region of the second semiconductor substrate opposed to a pixel part including the sensor pixel, and the logic circuit is provided in a region opposed to a peripheral part around the pixel part.

The present application claims the benefit of Japanese Priority Patent Application JP2021-091939 filed with the Japan Patent Office on May 31, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An image sensor comprising:
a wiring layer including multiple wires extending in one direction;
a first insulating layer with air gaps formed in at least some of regions between adjacent wires of the multiple wires;
a first conducting film formed and embedded in a first surface of the first insulating layer in a first region including the air gaps and the adjacent wires between which the air gaps have been formed; and
a second conducting film formed and embedded in the first surface of the first insulating layer in a second region not including the air gaps and the adjacent wires between which the air gaps have been formed, the second conducting film being thicker than the first conducting film.

2. The image sensor according to claim 1, wherein respective surfaces of the first conducting film and the second conducting film are exposed on the first surface of the first insulating layer.

3. The image sensor according to claim 1, wherein the first conducting film and the second conducting film are independent from each other with the first insulating layer between the first conducting film and the second conducting film.

4. The image sensor according to claim 1, wherein the first conducting film and the second conducting film form a continuous conducting film, and inside of the conducting film has different in-plane thicknesses.

5. The image sensor according to claim 1, wherein the first insulating layer is formed using a low-dielectric constant material having a relative dielectric constant k of 3.0 or lower.

6. The image sensor according to claim 1, further comprising a barrier film stacked on the wiring layer, an end surface of the barrier film being located above any of the multiple wires.

7. The image sensor according to claim 6, further comprising a second insulating layer provided between the first insulating layer and the barrier film and extending over the end surface, upper and side surfaces of the multiple wires, and below the air gaps.

8. The image sensor according to claim 1, further comprising:
a first substrate including a first semiconductor substrate including a sensor pixel that performs photoelectric conversion and a first multi-layer wiring layer including the wiring layer, the first insulating layer, the first conducting film, and the second conducting film; and
a second substrate including a second semiconductor substrate including a logic circuit that processes a pixel signal based on an electric charge output from the sensor pixel and a second multi-layer wiring layer formed and embedded with one or more third conducting films on a second surface in a side opposite to a side of the second semiconductor substrate,
wherein the first substrate and the second substrate are electrically coupled to each other by joining of the first conducting film and the second conducting film to the one or more third conducting films.

9. The image sensor according to claim 8, wherein the first substrate further includes a third semiconductor substrate provided with a readout circuit between the first semiconductor substrate and the first multi-layer wiring layer, the readout circuit outputting the pixel signal based on the electric charge output from the sensor pixel to the logic circuit.

10. The image sensor according to claim 8, wherein
the second substrate further includes a readout circuit that outputs the pixel signal based on the electric charge output from the sensor pixel to the logic circuit, and
the readout circuit is provided in a region of the second semiconductor substrate opposed to a pixel part including the sensor pixel, and the logic circuit is provided in a region opposed to a peripheral part around the pixel part.
